(19) United States
(12) Patent Application Publication
(10) Pub. No.: US 2025/0374535 A1
(43) Pub. Date: Dec. 4, 2025

(54) SEMICONDUCTOR DEVICES

(71) Applicant: Samsung Electronics Co., Ltd., Suwon-si (KR)

(72) Inventors: Jonghyuk Kim, Suwon-si (KR); Bokyeon Won, Suwon-si (KR); In Jung, Suwon-si (KR); Sujin Park, Suwon-si (KR)

(21) Appl. No.: 19/092,292

(22) Filed: Mar. 27, 2025

(30) Foreign Application Priority Data
May 28, 2024 (KR) 10-2024-0069379

(51) Int. Cl. H10B 12/00

(52) U.S. Cl. CPC H10B 12/50; H10B 12/315

(57) ABSTRACT

The semiconductor device includes first and second active patterns spaced apart from each other in a first direction; a first gate structure extending in a second direction on the first active pattern; a second gate structure extending in the second direction on the second active pattern; a first impurity region at an upper portion of the first active pattern adjacent to a first side of the first gate structure; a second impurity region at an upper portion of the second active pattern adjacent to a second side of the second gate structure; first and second lower contact plugs contacting upper surfaces of the first and second impurity regions, respectively; a shared lower wiring contacting upper surfaces of the first and second lower contact plugs; and a first upper contact plug contacting an upper surface of the shared lower wiring.

### CROSS-REFERENCE TO RELATED APPLICATION

This application claims priority under 35 U.S.C. § 119 to Korean Patent Application No. 10-2024-0069379 filed on May 28, 2024 in the Korean Intellectual Property Office, the disclosure of which is hereby incorporated by reference in its entirety.

### TECHNICAL FIELD

Example embodiments of the present disclosure relate to a semiconductor device.

### BACKGROUND

Integrated circuits may be designed based on standard cells. Specifically, the standard cells may be placed based on data defining the integrated circuit, and the layout of the integrated circuit may be created by routing the standard cells. The standard cells may be predesigned and stored in a cell library.

As the method of manufacturing the semiconductor device may become more advanced, the size of patterns within the standard cell may shrink leading to corresponding reduction in the size of the standard cell as well.

### SUMMARY

Example embodiments provide a semiconductor device having improved electrical characteristics.

According to example embodiments of the inventive concepts, there is a semiconductor device. The semiconductor device may include a first active pattern a second active pattern on a substrate, the first and second active patterns spaced apart from each other in a first direction substantially parallel to an upper surface of the substrate; a first gate structure extending in a second direction on the first active pattern, the second direction substantially parallel to the upper surface of the substrate and intersecting the first direction; a second gate structure extending in the second direction on the second active pattern and spaced apart from the first gate structure in the first direction; a first impurity region in an upper portion of the first active pattern and adjacent to a first side of the first gate structure facing the second gate structure in the first direction; a second impurity region in the upper portion of the second active pattern and adjacent to a second side of the second gate structure facing the first gate structure in the first direction; a first lower contact plug and a second lower contact plug contacting an upper surface of the first impurity region and an upper surface of the second impurity region, respectively; a shared lower wiring contacting upper surfaces of the first and second lower contact plugs; and a first upper contact plug contacting an upper surface of the shared lower wiring.

According to example embodiments of the inventive concepts, there is a semiconductor device. The semiconductor device may include a first active pattern a second active pattern on a substrate, the first and second active patterns spaced apart from each other in a first direction substantially parallel to an upper surface of the substrate; a first gate structure and a second gate structure each extending in a second direction on the first active pattern and spaced apart from each other in the first direction, the second direction substantially parallel to the upper surface of the substrate and intersecting the first direction; a third gate structure extending in the second direction on the second active pattern; a first source region in an upper portion of the first active pattern and adjacent to a first side of the first gate structure; a first drain region in the upper portion of the first active pattern and adjacent to a second side of the first gate structure and a third side of the second gate structure facing each other in the first direction; a second source region in the upper portion of the first active pattern and adjacent to a fourth side of the second structure that is opposite to the third side of the second gate structure in the first direction; a third source region in an upper portion of the second active pattern and adjacent to a fifth side of the third gate structure facing the fourth side of the second gate structure in the first direction; a second drain region in the upper portion of the second active pattern and adjacent to a sixth side of the third gate structure facing the fifth side of the third gate structure in the first direction; a first contact plug, a second lower contact plug and a third lower contact plug on the first to third source regions, respectively; a first lower wiring contacting an upper surface of the first contact plug; and a second lower wiring contacting upper surfaces of the second and third lower contact plugs, wherein a width in the first direction of the second lower wiring is greater than a width in the first direction of the first lower wiring.

According to example embodiments of the inventive concepts, there is a semiconductor device. The semiconductor device may include a cell active pattern on a substrate including a cell region and a peripheral circuit region; a cell gate structure extending in a first direction substantially parallel to an upper surface of the substrate and in an upper portion of the cell active pattern; a bit line structure contacting a central portion of an upper surface of the cell active pattern and extending in a second direction substantially parallel to the upper surface of the substrate and substantially perpendicular to the first direction; a contact plug structure contacting a first end and a second end of the upper surface of the cell active pattern; a capacitor on the contact plug structure; a peripheral active pattern on the peripheral circuit region; a first peripheral gate structure and a second peripheral gate structure extending in a third direction on the peripheral active pattern and spaced apart from each other in a fourth direction, the third and fourth directions substantially parallel to the upper surface of the substrate and intersecting each other; a first impurity region in an upper portion of the peripheral active pattern adjacent to a first side of the first peripheral gate structure facing the second peripheral gate structure in the fourth direction; a second impurity region in the upper portion of the peripheral active pattern adjacent to a second side of the second peripheral gate structure facing the first peripheral gate structure in the fourth direction; a first lower contact plug and a second lower contact plug contacting an upper surface of the first impurity region and an upper surface of the second impurity region, respectively; a shared lower wiring commonly contacting upper surfaces of the first and second lower contact plugs; and an upper contact plug contacting an upper surface of the shared lower wiring.

In the semiconductor device, the first and second source regions of the respective first and second transistors of the standard cell may be electrically connected to the power rail by a single contact plug. Accordingly, compared to a case where the first and second source regions are electrically connected to the power rail by separate contact plugs, the degree of integration of the semiconductor device including the standard cell may be improved.

### BRIEF DESCRIPTION OF THE DRAWINGS

FIGS. 1 to 7 are plan views and cross-sectional views illustrating a semiconductor device according to example embodiments.

FIGS. 8 to 58 are plan views and cross-sectional views illustrating a method of manufacturing a semiconductor device according to example embodiments.

FIGS. 59 and 60 are cross-sectional views illustrating a semiconductor device according to example embodiments.

### DETAILED DESCRIPTION

The above and other aspects and features of a decoupling capacitor structure and a method of forming the same, and a semiconductor device including the decoupling capacitor structure and a method of manufacturing the same in accordance with example embodiments will become readily understood from detail descriptions that follow, with reference to the accompanying drawings. It will be understood that, although the terms “first,” “second,” and/or “third” may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second or third element, component, region, layer or section without departing from the teachings of inventive concepts.

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection.

Hereinafter, in the specification (and not necessarily in the claims), two directions substantially parallel to an upper surface of first and second regions I and II of a substrate 100 and substantially perpendicular to each other may be referred to as first and second directions D1 and D2, respectively, and a direction substantially parallel to the upper surface of the first and second regions I and II of the substrate 100 and having an acute angle with respect to each of the first and second direction D1 and D2 may be referred to as a third direction D3. Two directions substantially parallel to an upper surface of a third region III of the substrate 100 and substantially perpendicular to each other may be referred to as fourth and fifth directions D4 and D5, respectively. A direction substantially perpendicular to the upper surface of the substrate 100 may be referred to as a vertical direction.

Each of the first to fifth directions D1, D2, D3, D4 and D5 may represent not only a direction shown in the drawings, but also a reverse direction of the direction shown in the drawings.

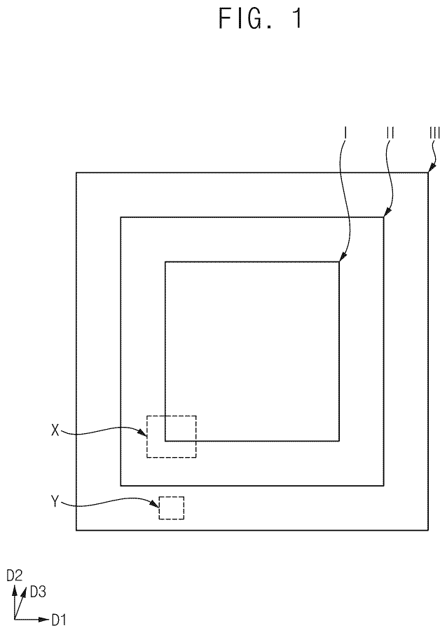

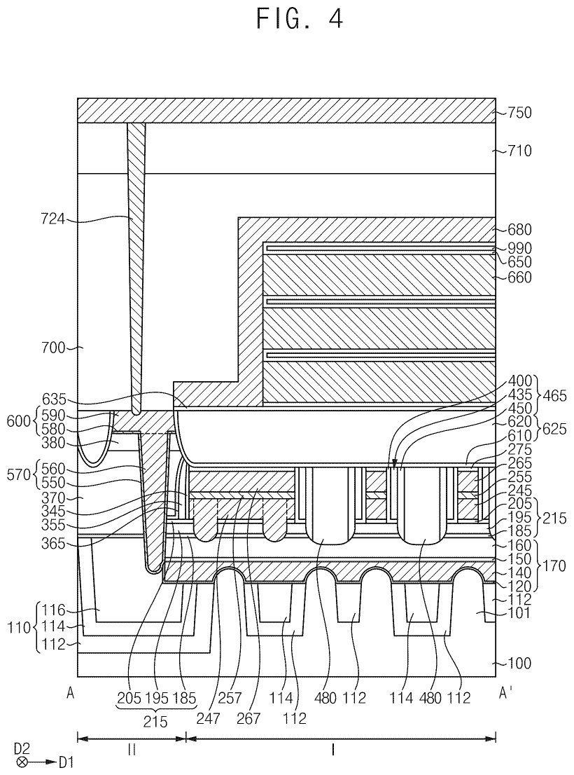

FIGS. 1 to 3 are plan views illustrating a semiconductor device according to example embodiments, and FIGS. 4 to 7 are cross-sectional views illustrating a semiconductor device according to example embodiments.

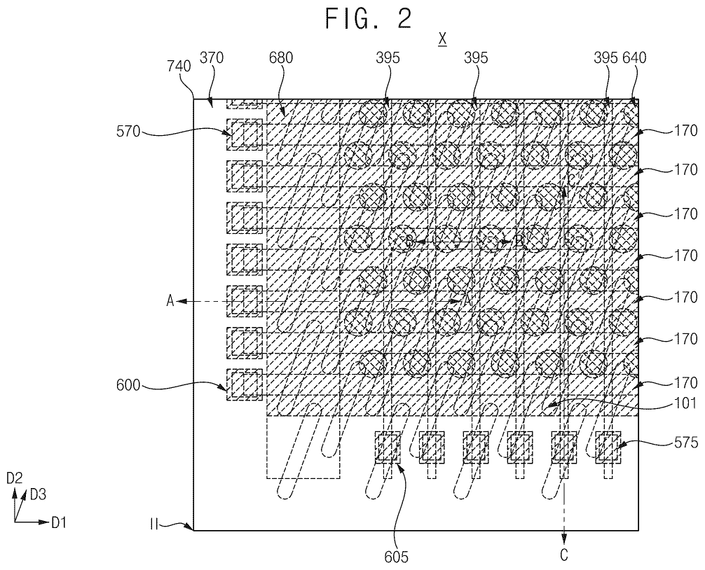

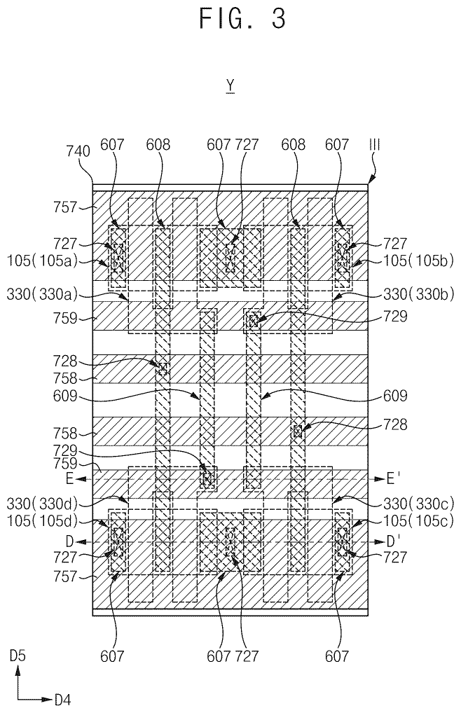

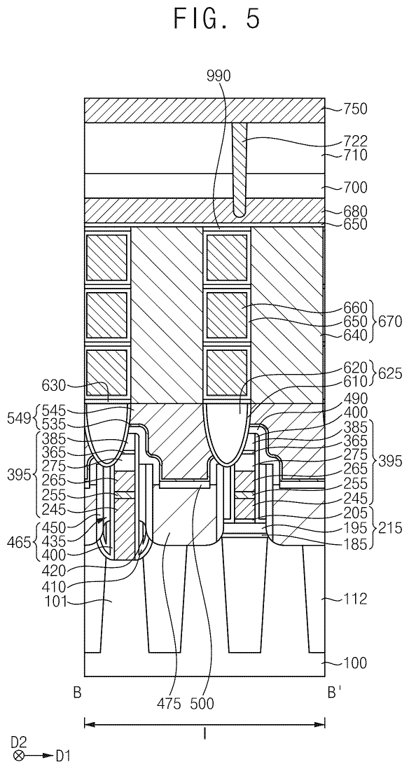

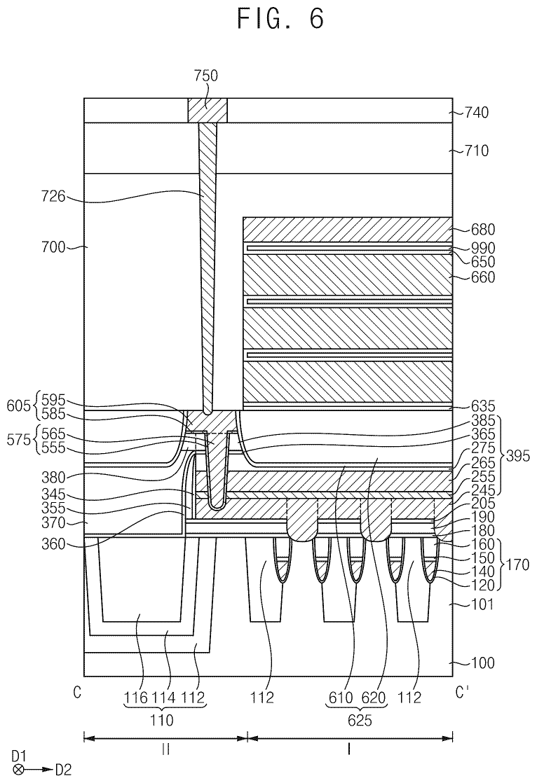

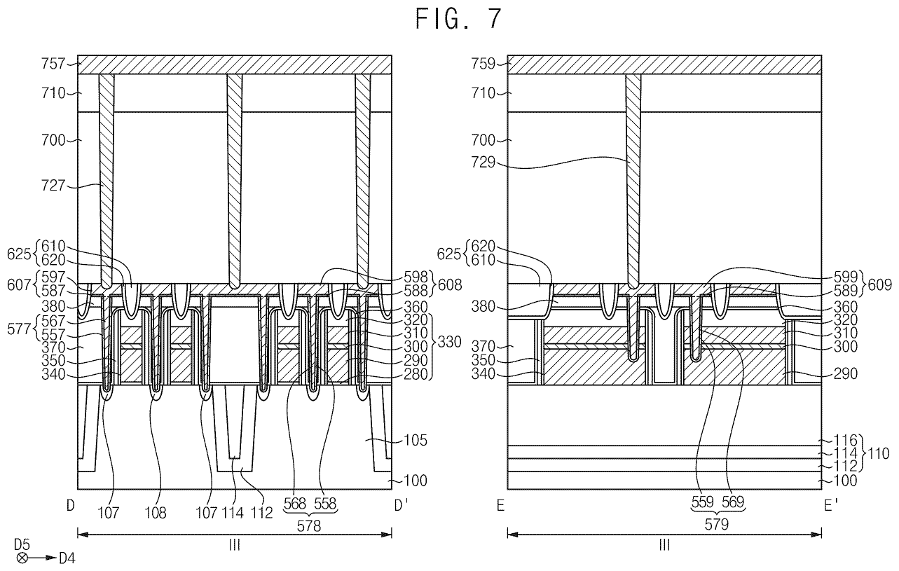

Specifically, FIG. 2 is an enlarged plan view of region X of FIG. 1, and FIG. 3 is an enlarged plan view of region Y of FIG. 1. First upper wiring 750 is not illustrated in FIG. 2 to avoid complexity. FIG. 4 is a cross-sectional view taken along line A-A′ of FIG. 2, FIG. 5 is a cross-sectional view taken along line B-B′ of FIG. 2, and FIG. 6 is a cross-sectional view taken along line C-C′ of FIG. 2. FIG. 7 includes cross-sectional views taken along lines D-D′ and E-E′ of FIG. 3.

FIG. 3 may be a layout of a standard cell. However, the layout of the standard cell may not be limited to thereto.

Referring to FIGS. 1 to 7, the semiconductor device may include a cell active pattern 101, a peripheral active pattern 105, first and second impurity regions 107 and 108, a cell gate structure 170, a peripheral gate structure 330, a bit line structure 395, a dummy bit line structure 397, a contact plug structure, first to fifth lower wirings 600, 605, 607, 608 and 609, a capacitor 670, first to sixth upper contact plugs 722, 724, 726, 727, 728 and 729 and first, fourth, fifth and sixth upper wirings 750, 757, 758 and 759 on the substrate 100.

The semiconductor device may further include an isolation structure 110, an insulation structure 215, first and second spacer structures, fourth and fifth insulation pattern 410 and 420, a third spacer structure 465, an eighth spacer 490, a fence pattern 480, first, third, fourth and fifth insulating interlayers 370, 700, 710 and 740, a second insulating interlayer 625, a support layer 990 and a plate electrode 680.

The substrate 100 may include silicon, germanium, silicon-germanium, or a III-V group compound semiconductor, such as GaP, GaAs, or GaSb. In example embodiments, the substrate 100 may be a silicon-on-insulator (SOI) substrate or a germanium-on-insulator (GOI) substrate.

The first region I of the substrate 100 may be a cell array region on which memory cells are formed, and the second region II of the substrate 100 may be an extension region on which contact plugs that transmit electrical signals to memory cells are formed. The first and second regions I and II may collectively form a cell region. The third region III of the substrate 100 at least partially surrounding the first and second regions I and II of the substrate 100 may be a peripheral circuit region on which peripheral circuit patterns for driving the memory cells are formed.

The cell active pattern 101 may extend in the third direction D3 on the first region I of the substrate 100 and the second region II of the substrate 100 adjacent thereto, and a plurality of cell active patterns 101 may be spaced apart from each other in the first and second directions D1 and D2. A plurality of peripheral active patterns 105 may be spaced apart from each other in the fourth and fifth directions D4 and D5 directions on the third region III of the substrate 100.

Hereinafter, for convenience of explanation, the peripheral active patterns 105 may be referred to as first to fourth peripheral active patterns 105a, 105b, 105c and 105d, respectively, in a clockwise direction.

Sidewalls of the cell active pattern 101 and the peripheral active pattern 105 may be covered or at least partially overlapped by the isolation structure 110. Each of the cell active pattern 101 and the peripheral active pattern 105 may include substantially the same material as the substrate 100, and the isolation structure 110 may include an oxide, e.g., silicon oxide.

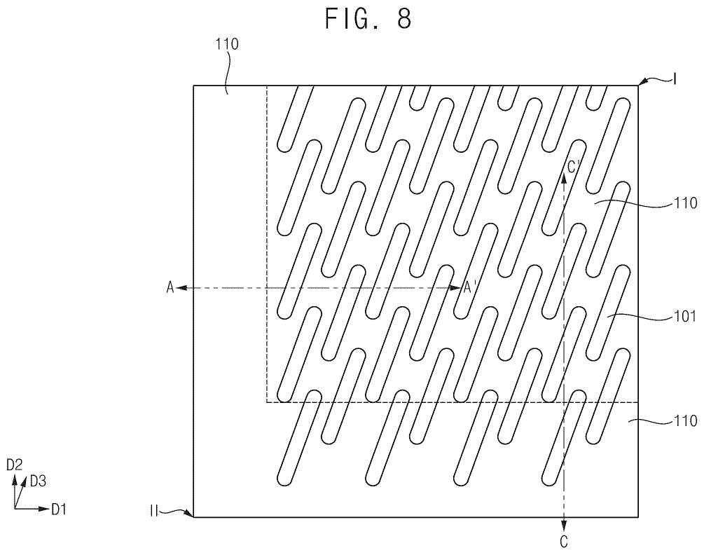

Referring to FIGS. 1 to 7 together with FIGS. 8 to 12, the isolation structure 110 may include first, second and third isolation patterns 112, 114 and 116 sequentially stacked on an inner wall of the third recess 106. However, the first and second isolation patterns 112 and 114 may be formed in the second recess 104 having a width smaller than that of the third recess 106, and the first isolation pattern 112 only may be formed in the first recess 102 having a width smaller than that of the second recess 104.

Each of the first and third isolation patterns 112 and 116 may include an oxide, e.g., silicon oxide, and the second isolation pattern 114 may include an insulating nitride, e.g., silicon nitride.

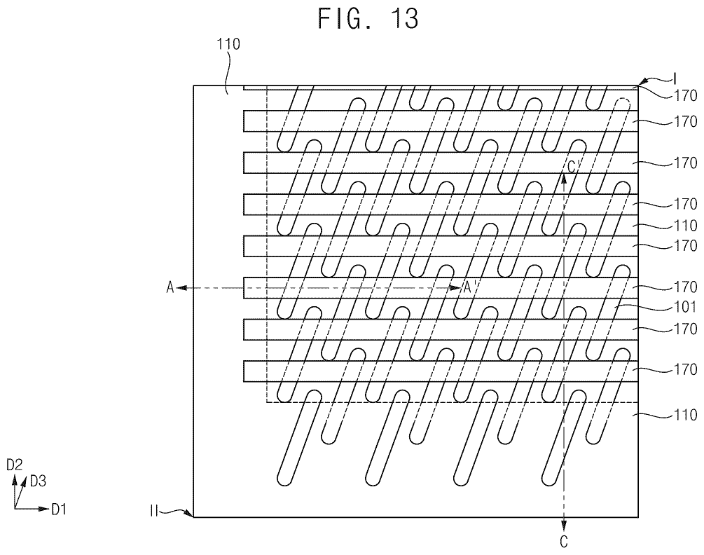

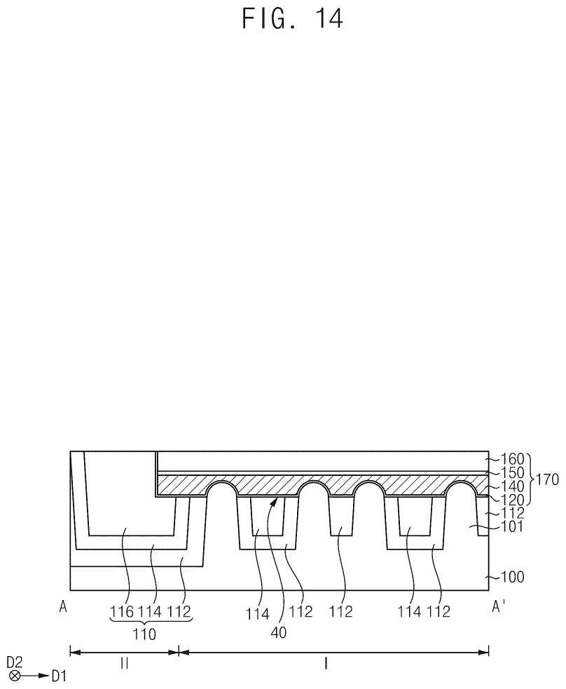

Referring to FIGS. 1 to 7 together with FIGS. 13-14, the cell gate structure 170 may be formed within the fourth recess 40 extending through the cell active pattern 101 and the isolation structure 110 in the first direction D1 on the first region I of the substrate 100 and the second region II of the substrate 100 adjacent thereto.

The cell gate structure 170 may include a first gate insulation pattern 120 on a bottom and a sidewall of the fourth recess 40, a first gate electrode on a portion of the first gate insulation pattern 120 on the bottom and a lower sidewall of the fourth recess 40, and a first gate mask 160 on the first gate electrode and at least partially filling an upper portion of the fourth recess 40. The first gate electrode may include first and second conductive patterns 140 and 150 sequentially stacked in the third direction D3, and a first barrier pattern may be further formed between the first gate insulation pattern 120 and the first conductive pattern 140.

The first gate insulation pattern 120 may include an oxide, e.g., silicon oxide, the first barrier pattern may include a metal nitride, e.g., titanium nitride, tantalum nitride, etc., the first conductive pattern 140 may include a metal, e.g., tungsten, a metal nitride, e.g., titanium nitride, tantalum nitride, etc., a metal silicide, polysilicon doped with impurities, etc., the second conductive pattern 150 may include polysilicon doped with impurities, and the first gate mask 160 may include an insulating nitride, e.g., silicon nitride.

In example embodiments, the cell gate structure 170 may extend in the first direction D1 on the first region I of the substrate 100 and the second region II of the substrate 100 adjacent thereto, and a plurality of cell gate structures 170 may be spaced apart from each other in the second direction D2. End portions in the first direction D1 of the cell gate structures 170 may be aligned with each other in the second direction D2 on the second region II of the substrate 100.

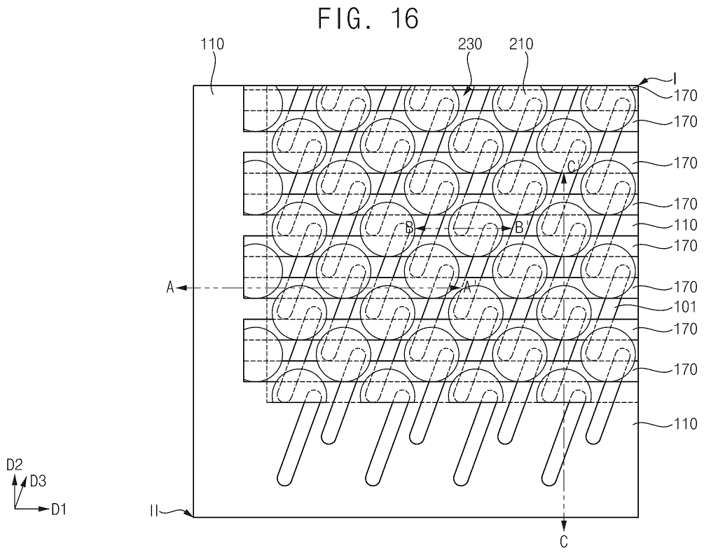

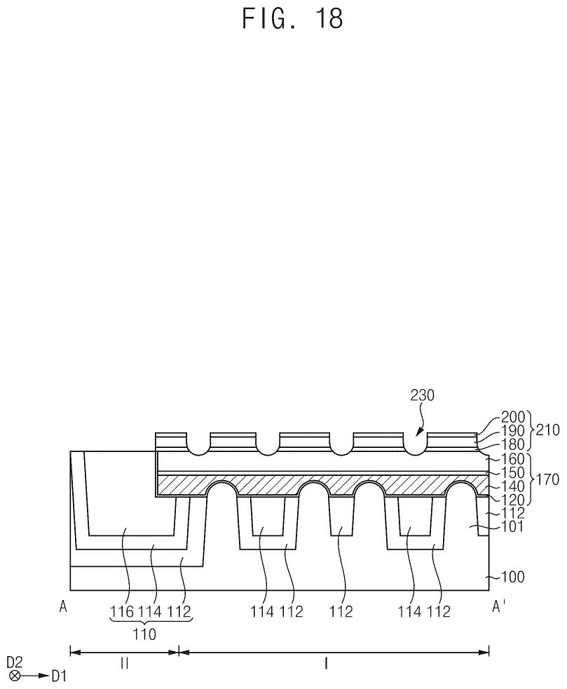

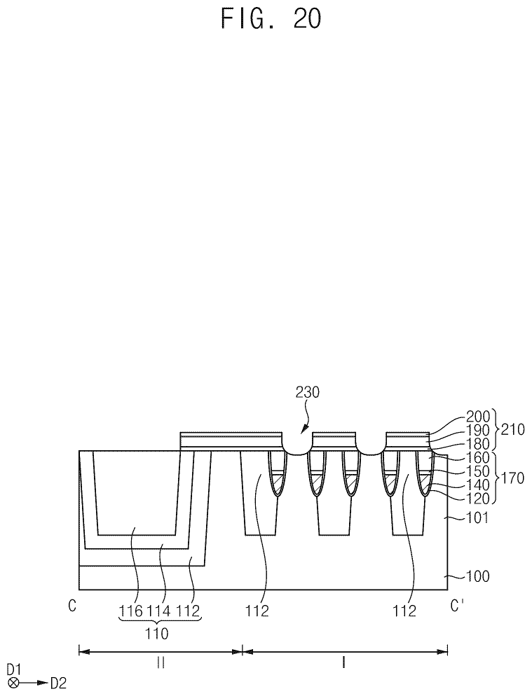

Referring to FIGS. 1 to 7 together with FIG. 16 and FIGS. 18 and 20, a first opening 230 extending through an insulation layer structure 210 and exposing upper surfaces of the cell active pattern 101, the isolation structure 110 and the first gate mask 160 of the cell gate structure 170 may be formed, and an upper surface of a central portion in the third direction D3 of the cell active pattern 101 may be exposed by the first opening 230.

In example embodiments, an area of a bottom of the first opening 230 may be greater than an area of the upper surface of the cell active pattern 101. Thus, the first opening 230 may also expose an upper surface of a portion of the isolation structure 110 adjacent to the cell active pattern 101. Additionally, the first opening 230 may extend through upper portions of the cell active pattern 101 and the portion of the isolation structure 110 adjacent thereto, and thus the bottom of the first opening 230 may be lower than an upper surface of each of opposite edge portions in the third direction D3 of the cell active pattern 101.

The bit line structure 395 may include a fifth conductive pattern 245, a third barrier pattern 255, a sixth conductive pattern 265, a first mask 275, a first etch stop pattern 365 and a first capping pattern 385 sequentially stacked in the vertical direction on the first opening 230 or the insulation pattern structure 215. The fifth conductive pattern 245, the third barrier pattern 255 and the sixth conductive pattern 265 may collectively form a conductive structure, and the first mask 275, the first etch stop pattern 365 and the first capping pattern 385 may collectively form an insulation structure. In example embodiments, the bit line structure 395 may extend in the second direction D2 on the first region I of the substrate 100 and the second region II of the substrate 100 adjacent thereto in the second direction D2, and a plurality of bit line structures 395 may be spaced apart from each other in the first direction D1.

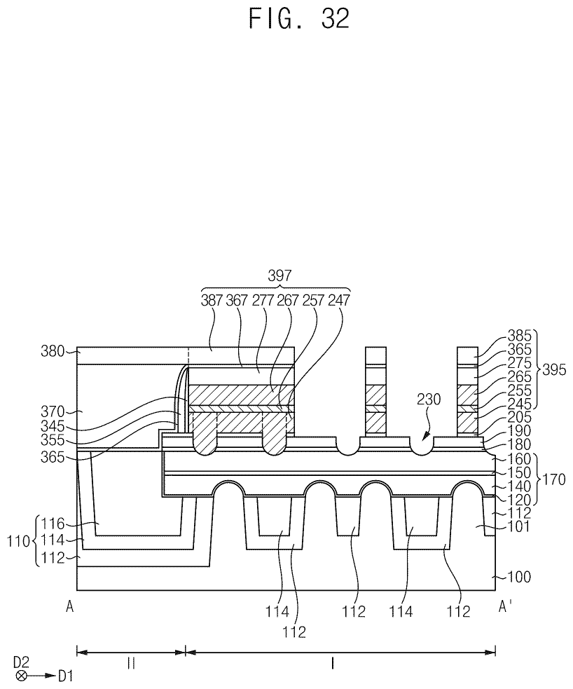

Referring to FIGS. 1 to 7 together with FIG. 32, the dummy bit line structure 397 may include a seventh conductive pattern 247, a fourth barrier pattern 257, an eighth conductive pattern 267, a second mask 277, a second etch stop pattern 367 and a second capping pattern 387 sequentially stacked in the vertical direction on the portion of the first region I of the substrate 100 adjacent to the second region II of the substrate 100. In example embodiments, the dummy bit line structure 397 may extend in the second direction D2 on the first region I of the substrate 100 adjacent to the second region II of the substrate 100 in the first direction D1.

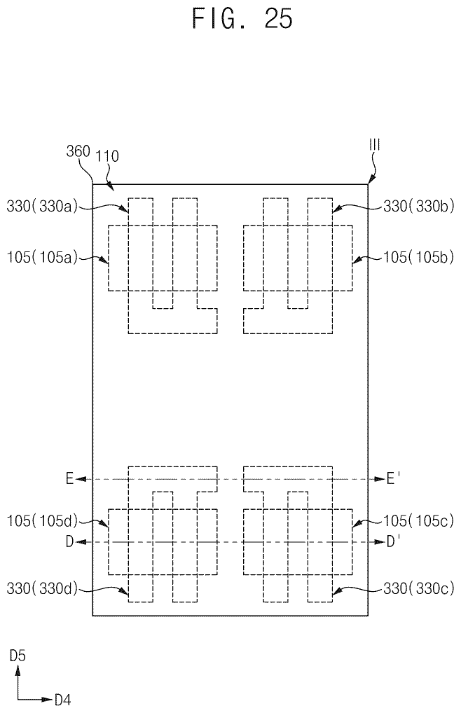

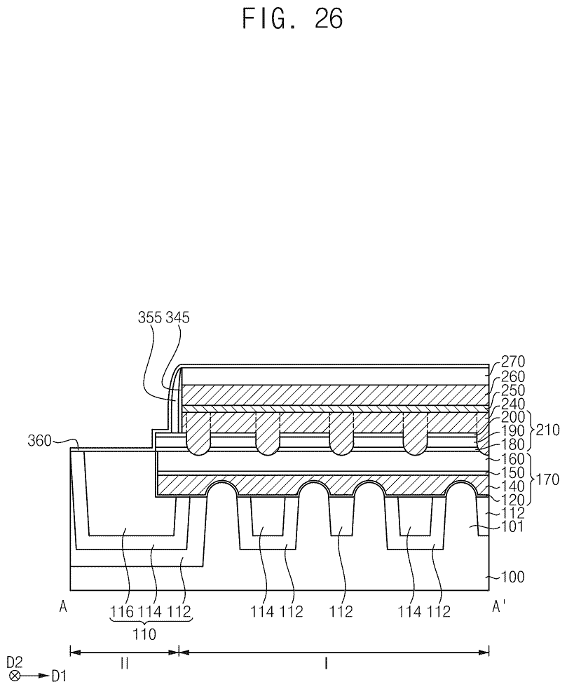

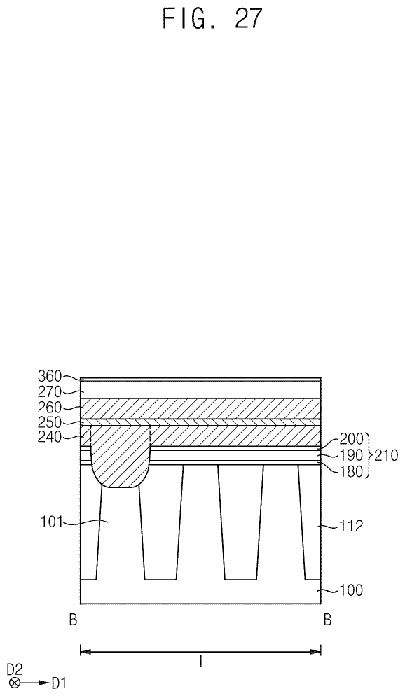

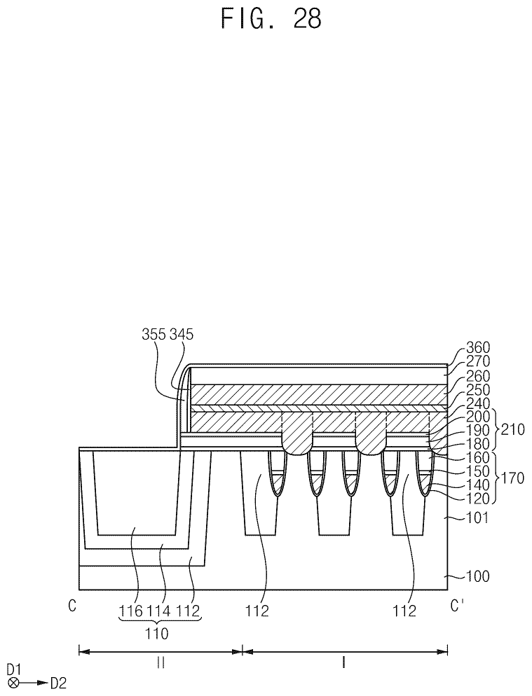

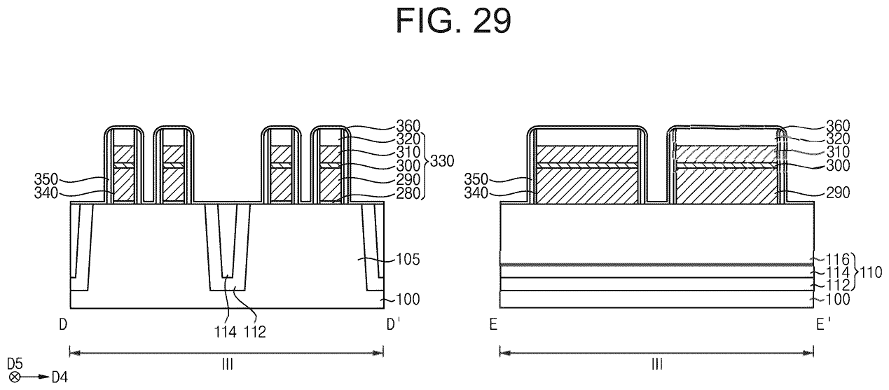

Referring of FIGS. 1 to 6 together with FIGS. 25 to 29, the peripheral gate structure 330 may include a second gate insulation pattern 280, a third conductive pattern 290, a second barrier pattern 300, a fourth conductive pattern 310 and a second gate mask 320 sequentially stacked in the vertical direction on the third region of the substrate 100. The third conductive pattern 290, the second barrier pattern 300 and the fourth conductive pattern 310 sequentially stacked may together form a second gate electrode.

In example embodiments, the peripheral gate structure 330 may include a first extension portion and a second extension portion. The first extension portion may extend in the fifth direction D5 and a plurality of first extension portions may be spaced apart from each other in the fourth direction D4. The first extension portion may at least partially overlap the peripheral active pattern 105 in the vertical direction. The second extension portion may extend in the first direction D1 on the isolation structure 110 while contacting end portions in the fifth direction D5 of the first extension portions. In example embodiments, an end portion of the second extension in the fourth direction D4 may protrude or extend in the fourth direction D4 from a side in the fourth direction D4 of the first extension to form a protrusion.

In the drawings, the peripheral gate structure 330 includes two first extension portions and one second extension portion. However, the concept of the present disclosure is not limited thereto. That is, the peripheral gate structure 330 may include one, three or more first extension portions, and may include two or more second extension portions.

In example embodiments, the peripheral gate structure 330 may be formed on the peripheral active pattern 105, and a plurality of peripheral gate structures 330 may be spaced apart from each other in the fourth and fifth directions D4 and D5. Hereinafter, for convenience of explanation, the peripheral gate structures 330 respectively formed on the first to fourth peripheral active patterns 105a, 105b, 105c and 105d may be to referred as first to fourth peripheral gate structures 330a, 330b, 330c and 330d, respectively.

In example embodiments, the second extension portions of the first and fourth peripheral gate structures 330a and 330d may face each other in the fifth direction D5, and the second extension portions of the second and third peripheral gate structures 330b and 330c may face each other in the fifth direction D5. In example embodiments, the protrusions of the first and fourth peripheral gate structures 330a and 330d may be aligned with each other in the fifth direction D5, and the protrusions of the second and third peripheral gate structures 330b and 330c may be aligned with each other in the fifth direction D5. In example embodiments, the second extensions of the first and second peripheral gate structures 330a and 330b may be aligned with each other in the fourth direction D4, and the second extensions the third and fourth peripheral gates 330c and 330d may be aligned with each other in the fourth direction D4.

Each of the third, fifth and seventh conductive patterns 290, 245 and 247 may include, e.g., doped polysilicon. Each of the second to fourth barrier patterns 300, 255 and 257 may include a metal nitride, e.g., titanium nitride, or a metal silicon nitride, e.g., titanium silicon nitride. Each of the fourth, sixth and eighth conductive pattern 310, 265 and 267 may include a metal, e.g., tungsten. Each of the first and second masks 275 and 277, the second gate mask 320, each of the first and second etch stop patterns 365 and 367 and each of the first and second capping patterns 385 and 387 may include an insulating nitride, e.g., silicon nitride.

Each of the first and second impurity regions 107 and 108 may be formed on an upper portion of the peripheral active pattern 105 adjacent to the peripheral gate structure 330. The second impurity region 108 may be formed at an upper portion of the peripheral active pattern 105 between second sides of the first extensions of the peripheral gate structure 330 facing each other in the fourth direction D4, and the first impurity region 107 may be formed at an upper portion of the peripheral active pattern 105 adjacent to a first side of the first extension of the peripheral gate structure 330 that is opposite from the second side of the first extension of the peripheral gate structure 330 in the fourth direction D4. In example embodiments, the first impurity region 107 may serve as a source, and the second impurity region 108 may serve as a drain. The first extensions of the peripheral gate structure 330 may share the second impurity region 108.

The first spacer structure may be formed at a sidewall of the peripheral gate structure 330, and the second spacer structure may be formed at a sidewall of the bit line structure 395 and a sidewall of the dummy bit line structure 397 adjacent to the second region II of the substrate 100. The first spacer structure may include first and third spacers 340 and 350 stacked on the sidewall of the peripheral gate structure 330 in a horizontal direction substantially parallel to the upper surface of the substrate 100, and the second spacer structure may include second and fourth spacers 345 and 355 stacked on the sidewall of the bit line structure 395 and the sidewall of the dummy bit line structure 397 in the horizontal direction.

The first and second spacers 340 and 345 may include a nitride, e.g., silicon nitride, and the third and fourth spacers 350 and 355 may include an oxide, e.g., silicon oxide.

However, the structure of the first and second spacer structures may not be limited thereto, and each of the first and second spacer structures may include a single spacer or more than two spacers sequentially stacked.

The fourth and fifth insulation patterns 410 and 420 may be formed in the first opening 230, and may contact a lower sidewall of the bit line structure 395. The fourth insulation pattern 410 may include an oxide, e.g., silicon oxide, and the fifth insulation pattern 420 may include an insulating nitride, e.g., silicon nitride.

The insulation pattern structure 215 may be formed on the cell active pattern 101 and the isolation structure 110 under the bit line structure 395, and may include first, second and third insulation patterns 185, 195 and 205 sequentially stacked in the vertical direction. The first and third insulation patterns 185 and 205 may include an oxide, e.g., silicon oxide, and the second insulation pattern 195 may include an insulating nitride, e.g., silicon nitride.

The contact plug structure may include a first contact plug 475, an ohmic contact pattern 500 and a second contact plug 549 sequentially stacked in the vertical direction on the cell active pattern 101 and the isolation structure 110.

The first contact plug 475 may contact the upper surface of each of opposite edge portions in the third direction D3 of the cell active pattern 101. In example embodiments, a plurality of first contact plugs 475 may be spaced apart from each other in the second direction D2 between the bit line structures 395 on the first region I of the substrate 100 and between the bit line structure 395 and the dummy bit line structure 397, and a fence pattern 480 may be formed between neighboring ones of the first contact plugs 475 in the second direction D2. The fence pattern 480 may include an insulating nitride, e.g., silicon nitride.

The first contact plug 475 may include, e.g., doped polysilicon, the ohmic contact pattern 500 may include, e.g., titanium silicide, cobalt silicide, nickel silicide, etc.

The second contact plug 549 may include a first metal pattern 545 and a fifth barrier pattern 535 covering or at least partially overlapping a lower surface of the first metal pattern 545. The first metal pattern 545 may include a metal, e.g., tungsten, and the fifth barrier pattern 535 may include a metal nitride, e.g., titanium nitride.

In example embodiments, a plurality of second contact plugs 549 may be spaced apart from each other in the first and second directions D1 and D2 on the first region I of the substrate 100, and may be arranged in a honeycomb pattern or a lattice pattern in a plan view. Each of the second contact plugs 549 may have a shape of, e.g., a circle, an ellipse, or a polygon in a plan view.

The third spacer structure 465 may include a fifth spacer 400 covering or at least partially overlapping sidewalls of the bit line structure 395, the third insulation pattern 205 and the dummy bit line structure 397, an air spacer 435 on a lower outer sidewall of the fifth spacer 400, and a seventh spacer 450 on an outer sidewall of the air spacer 435, a sidewall of the insulation pattern structure 215, and upper surfaces of the fourth and fifth insulation patterns 410 and 420.

Each of the fifth and seventh spacers 400 and 450 may include an insulating nitride, e.g., silicon nitride, and the air spacer 435 may include air.

The eighth spacer 490 may be formed on an outer sidewall of a portion of the fifth spacer 400 on upper sidewalls of the bit line structure 395 and the dummy bit line structure 397, and may cover an upper end of the air spacer 435 and an upper surface of the seventh spacer 450. The eighth spacer 490 may include an insulating nitride, e.g., silicon nitride.

The first lower contact plug 570 may include a second metal pattern 560 and a sixth barrier pattern 580 covering or at least partially overlapping a sidewall and a lower surface thereof. The first lower contact plug 570 may extend through the capping layer 380 and the first insulating interlayer 370 on the second region II of the substrate 100 to contact the first conductive pattern 140 of the cell gate structure 170. In example embodiments, the first lower contact plug 570 may be formed on the portion of the second region II of the substrate 100 adjacent to the first region I of the substrate 100 in the first direction D1, and a plurality of first lower contact plugs 570 may be spaced apart from each other in the second direction D2.

The first lower wiring 600 may include a third metal pattern 590 and a seventh barrier pattern 580 covering or at least partially overlapping a lower surface thereof. The first lower wiring 600 may contact the first lower contact plug 570, and may apply an electrical signal to the cell gate structure 170 through the first lower contact plug 570.

The second lower contact plug 575 may include a fourth metal pattern 565 and an eighth barrier pattern 555 covering or at least partially overlapping a sidewall and a lower surface thereof. The second lower contact plug 575 may extend through the first capping pattern 385, the first etch stop pattern 365, the sixth conductive pattern 265 and the third barrier pattern 255 on the second region II of the substrate 100 to contact the fifth conductive pattern 245 of the bit line structure 395. In example embodiments, the second lower contact plug 575 may be formed on the portion of the second region II of the substrate 100 adjacent to the first region I of the substrate 100 in the second direction D2, and a plurality second lower contact plugs 575 may be spaced apart from each other in the first direction D1.

The second lower wiring 605 may include a fifth metal pattern 595 and a ninth barrier pattern 585 covering or overlapping a lower surface thereof. The second lower wiring 605 may contact the second lower contact plug 575, and may apply an electrical signal to the bit line structure 395 through the second lower contact plug 575.

The third lower contact plug 577 may include a sixth metal pattern 567 and a tenth barrier pattern 557 covering or overlapping a sidewall and a lower surface thereof. The third lower contact plug 577 may extend through the capping layer 380 and the first insulating interlayer 370 on the third region III of the substrate 100 to contact an upper surface of the first impurity region 107. In example embodiments, a plurality of third lower contact plugs 577 may be spaced apart from each other in the fourth and fifth directions D4 and D5 on the third region III of the substrate 100.

The third lower wiring 607 may include a seventh metal pattern 597 and an eleventh barrier pattern 587 covering or at least partially overlapping a lower surface thereof. The third lower wiring 607 may contact the third lower contact plug 577, and may be electrically connected to the first impurity region 107 through the third lower contact plug 577. In example embodiments, a plurality of the third lower wirings 607 may be spaced apart from each other in the fourth and fifth directions D4 and D5 corresponding to the third lower contact plug 577.

Some of the third lower wirings 607 may commonly contact upper surfaces of the third lower contact plugs 577 respectively formed on the peripheral active patterns 105 adjacent to each other in the fourth direction D4.

Hereinafter, for convenience of explanation, the third lower wiring 607 that commonly contacts the upper surfaces of the third lower contact plugs 577 respectively formed on the first and second peripheral active patterns 105a and 105b adjacent to each other in the fourth direction D4 may be referred to as the first shared lower wiring, and the third lower wiring 607 that commonly contacts the upper surfaces of the third lower contact plugs 577 respectively formed on the third and fourth peripheral active patterns 105c and 105d adjacent to each other in the fourth direction D4 may be referred to as the second shared lower wiring. Accordingly, the first impurity regions 107 respectively formed on the first and second peripheral active patterns 105a and 105b adjacent to each other in the fourth direction D4 may share the first shared lower wiring, and the first impurity region 107 respectively formed on the third and fourth peripheral active patterns 105c and 105d adjacent to each other in the fourth direction D4 may share the second shared lower wiring.

In example embodiments, a width in the fourth direction of each of the first and second shared lower wirings may be greater than a width in the fourth direction D4 of each of the third lower wirings 607 excluding the first and second shared lower wirings.

The fourth lower contact plug 578 may include an eighth metal pattern 568 and a twelfth barrier pattern 558 covering or at least partially overlapping a sidewall and a lower surface thereof. The fourth lower contact plug 578 may extend through the capping layer 380 and the first insulating interlayer 370 on the third region III of the substrate 100 to contact an upper surface of the second impurity region 108. In example embodiments, a plurality of fourth lower contact plugs 578 may be spaced apart from each other in the fourth and fifth directions D4 and D5 on the third region III of the substrate 100.

The fourth lower wiring 608 may include a ninth metal pattern 598 and a thirteenth barrier pattern 588 covering or at least partially overlapping a lower surface thereof. The fourth lower wiring 608 may at least partially overlap the fourth lower contact plug 578 in the vertical direction, and may be electrically connected to the second impurity region 108 through the fourth lower contact plug 578. In example embodiments, the fourth lower wiring 608 may extend in the fifth direction D5 and a plurality of fourth lower wirings 608 may be spaced apart from each other in the fourth direction D4.

In example embodiments, the fourth lower wiring 608 may extend in the fifth direction D5 and commonly contact upper surfaces of the fourth lower contact plugs 578 respectively formed on the peripheral active patterns 105 adjacent to each other in the fifth direction D5. That is, one of the fourth lower wirings 608 may commonly contact the upper surfaces of the fourth lower contact plugs 578 respectively formed on the first and fourth peripheral active patterns 105a and 105d, and accordingly, the second impurity regions 108 respectively formed on the first and fourth peripheral active patterns 105a and 105d may share the one of the fourth lower wirings 608.

A second one of the fourth lower wirings 608 may commonly contact the upper surfaces of the fourth lower contact plugs 578 respectively formed on the second and third peripheral active patterns 105b and 105c, and accordingly, the second impurity regions 108 respectively formed on the second and third peripheral active patterns 105b and 105c may share the second one of the fourth lower wirings 608.

The fifth lower contact plug 579 may include a tenth metal pattern 569 and a fourteenth barrier pattern 559 covering or overlapping a sidewall and a lower surface thereof. The fifth lower contact plug 579 may extend through the capping layer 380, the first etch stop layer 360, the second gate mask 320, the fourth conductive pattern 310 and the second barrier pattern 300 to contact the third conductive pattern 290 of the peripheral gate structure 330 on the third region III of the substrate 100. In example embodiments, the fifth lower contact plug 579 may at least partially overlap the protrusion of the peripheral gate structure 330 in the vertical direction. In example embodiments, a plurality of fifth lower contact plugs 579 may be spaced apart from each other in the fourth and fifth directions D4 and D5 on the third region III of the substrate 100.

The fifth lower wiring 609 may include an eleventh metal pattern 599 and a fifteenth barrier pattern 589 covering or at least partially overlapping a lower surface thereof. The fifth lower wiring 609 may contact the fifth lower contact plug 579, and may be electrically connected to the peripheral gate structure 330 through the fifth lower contact plug 579. In example embodiments, the fifth lower wiring 609 may extend in the fifth direction D5, and a plurality of fifth lower wirings 609 may be spaced apart from each other in the fourth direction D4.

In example embodiments, the fifth lower wiring 609 may extend in the fifth direction D5 and commonly contact the fifth lower contact plugs 579 respectively formed on the peripheral active patterns 105 adjacent to each other in the fifth direction D5.

In example embodiments, the second contact plug 549 and the first to fifth lower wirings 600, 605, 607, 608 and 609 may at least partially overlap each other in the horizontal direction. In example embodiments, the fifth lower wiring 609 may be an input line, and the fourth lower wiring 608 may be an output line.

In the drawing, the first extension portions of the peripheral gate structure 330 may be electrically connected to the fifth lower wiring 609, which is an input line, through the fifth lower contact plug 579 which is formed on the protrusion of the second extension portion. However, the concept of the present disclosure is not limited thereto. That is, the peripheral gate structure 330 may not include the second extension portion, and the first extension portion of the peripheral gate structure 330 may be electrically connected to a lower wiring, which is an input line, through a lower contact plug thereon.

Each of the first to eleventh metal patterns 545, 560, 590, 565, 595, 567, 597, 568, 598, 569 and 599 may include a metal, e.g., tungsten. Each of the fifth to fifteenth barrier patterns 535, 550, 580, 555, 585, 557, 587, 558, 588, 559 and 589 may include a metal nitride e.g., titanium nitride.

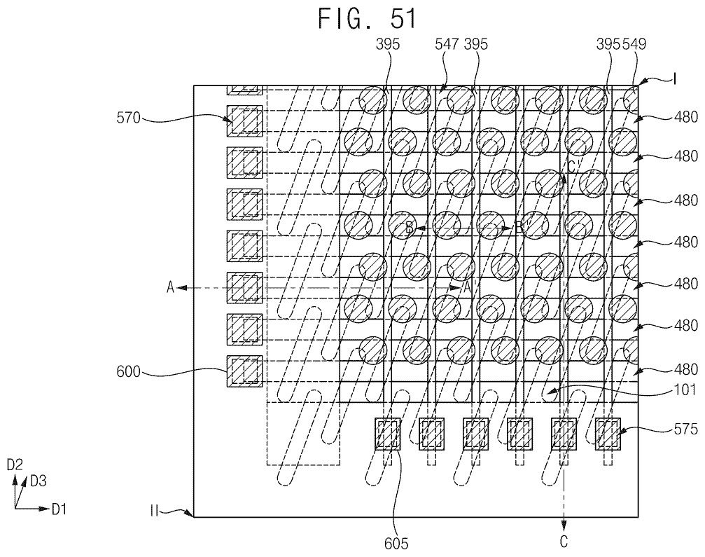

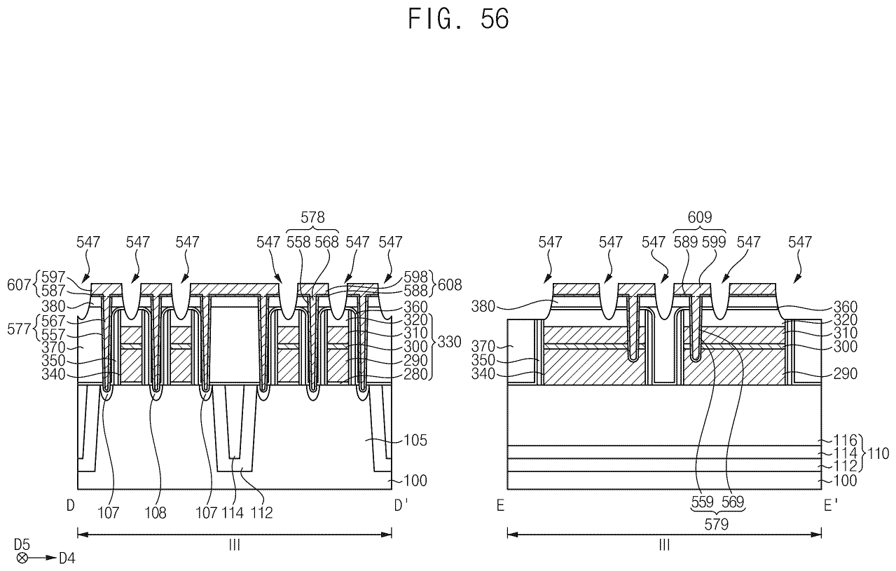

Referring to FIGS. 1 to 7 together with FIGS. 51 and 56, the second insulating interlayer 625 may include a sixth insulation pattern 610 on an inner wall of a twelfth opening 547, which may extend through the second contact plug 549, the first to fifth lower wirings 600, 605, 607, 608 and 609, a portion of the insulation structure of the bit line structure 395 and the dummy bit line structure 397, and portions of the fifth, seventh and eighth spacers 400, 450 and 490 and at least partially surround the second contact plug 549 and the first to fifth lower wirings 600, 605, 607, 608 and 609 in a plan view, and a seventh insulation pattern 620 on the sixth insulation pattern 610 and at least partially fill a remaining portion of the twelfth opening 547. The upper end of the air spacer 435 may be closed or at least partially surrounded by the sixth insulation pattern 610. The sixth and seventh insulation patterns 610 and 620 may include an insulating nitride, e.g., silicon nitride.

The second etch stop layer 630 may be formed on the sixth and seventh insulation patterns 610 and 620, the second contact plug 549 and the fence pattern 480 on the first region I of the substrate 100. The second etch stop layer 630 may include, an insulating nitride, e.g., silicon boronitride, silicon nitride, etc.

The capacitor 670 may include a first capacitor electrode 640, a dielectric layer 650 and a second electrode 660 sequentially stacked.

The first capacitor electrode 640 may extend through the second etch stop layer 630 to contact an upper surface of the second contact plug 549. Accordingly, a plurality of first capacitor electrodes 640 may be spaced apart from each other in the first and second directions D1 and D2. In example embodiments, the first capacitor electrode 640 may be arranged in a grid pattern or a honeycomb pattern in a plan view. The second contact plug 549 may serve as a landing pad for the first capacitor electrode 640.

The second etch stop layer 630 and the support layer 990 may be formed on a sidewall of each of the first capacitor electrodes 640. The second etch stop layer 630 may be formed at a lowermost sidewall of each of the first capacitor electrodes 640, and a plurality of support layers 990 may be formed at the sidewall of each of the first capacitor electrodes 640 and spaced apart from each other in the vertical direction.

The dielectric layer 650 may be formed on the sidewall of the first capacitor electrode 640, upper and lower surfaces and a sidewall of the support layer 990 and an upper surface of the second etch stop layer 630. The second capacitor electrode 660 may be formed between the support layer 990 adjacent to each other in the vertical direction and between a lowermost one of the support layers 990 and the second etch stop layer 630, and upper and lower surfaces and a sidewall of the second capacitor electrode 660 may be covered or at least partially overlapped by the dielectric layer 650.

The plate electrode 680 may cover or at least partially overlap upper surfaces and sidewalls of the capacitor 670, the support layer 990 and the second etch stop layer 630.

Each of the first capacitor electrode 640 and the second capacitor electrode 660 may include, e.g., metal, metal nitride, metal silicide, and the dielectric layer 650 may include, e.g., metal oxide. The support layer 990 may include an insulating nitride, e.g., silicon nitride, and the second etch stop layer 630 may include an insulating nitride, e.g., silicon boronitride. The plate electrode 680 may include, a metal e.g., tungsten, or silicon-germanium doped or undoped with impurities.

The third insulating interlayer 700 may be formed on the second contact plug 549, the first to fifth lower wirings 600, 605, 607, 608 and 609 and the second insulating interlayer 625 and cover or at least partially overlap sidewalls and upper surfaces of the capacitor 670 and the plate electrode 680.

The fourth and fifth insulating interlayers 710 and 740 may be sequentially formed on the third insulating interlayer 700. Each of the first, third, fourth and fifth insulating interlayers 370, 700, 710 and 740 may include an oxide, e.g., silicon oxide or a low dielectric material.

The first upper contact plug 722 may extend through the third and fourth insulating interlayers 700 and 710 on the first region I of the substrate 100 to contact an upper surface of the plate electrode 680. The second and third upper contact plugs 724 and 726 may extend through the third and fourth insulating interlayers 700 and 710 on the second region II of the substrate 100 and respectively contact upper surfaces of the first and second lower wirings 600 and 605.

The fourth to sixth upper contact plugs 727, 728 and 729 may extend through the third and fourth insulating interlayers 700 and 710 on the third region III of the substrate 100 and respectively contact upper surfaces of the third to fifth lower wirings 607, 608 and 609.

In example embodiments, each of the second to sixth upper contact plugs 724, 726, 727, 728 and 729 may at least partially overlap the capacitor 670 in the horizontal direction.

Each of the first to sixth upper contact plugs 722, 724, 726, 727, 728, and 729 may include a metal, e.g., tungsten, a metal nitride, e.g., titanium nitride, tantalum nitride, a metal silicide, polysilicon doped with impurities, etc.

The first upper wiring 750 may extend through the fifth insulating interlayers 740 on the first region I of the substrate 100 and/or the second region II of the substrate 100 and contact an upper surface of at least one of the first to third upper contact plugs 722, 724 and 726.

The fourth to sixth upper wirings 757, 758 and 759 may extend through the fifth insulating interlayer 740 on the third region III of the substrate 100 and respectively contact upper surfaces of the fourth to sixth upper contact plugs 726, 727 and 728. Accordingly, the fourth upper wiring 757 may be electrically connected to the first impurity region 107 through the fourth upper contact plug 727, the third lower wiring 607 and the third lower contact plug 577. The fifth upper wiring 758 may be electrically connected to the second impurity region 108 through the fifth upper contact plug 728, the fourth lower wiring 608 and the fourth lower contact plug 578. The sixth upper wiring 759 may be electrically connected to the peripheral gate structure 330 through the sixth upper contact plug 729, the fifth lower wiring 609 and the fifth lower contact plug 579.

In example embodiments, the fourth upper wiring 757 may extend in the fourth direction D4 and a plurality of fourth upper wirings 757 may be spaced apart from each other in the fifth direction D5. Specifically, the fourth upper wiring 757 may extend in the fourth direction D4 and contact upper surfaces of the fourth upper contact plugs 727 arranged along the fourth direction D4. Accordingly, all of the first impurity regions 107 formed on the first and second peripheral active patterns 105a and 105b may be electrically connected to one of the fourth upper wirings 757, and all of the first impurity regions 107 formed on the third and fourth peripheral active patterns 105c and 105d may be electrically connected to another one of the fourth upper wirings 757.

In example embodiments, the fifth upper wiring 758 may extend in the fourth direction D4 and a plurality of fifth upper wirings 758 may be spaced apart from each other in the fifth direction D5. In example embodiments, the sixth upper wiring 759 may extend in the fourth direction D4 and a plurality of sixth upper wirings 759 may be spaced apart from each other in the fifth direction D5.

In example embodiments, the fourth upper wiring 757 may serve as a power rail and may be a source power (VSS) line or a drain power (VDD) line. A width of the fourth upper wiring 757 in the fifth direction D5 may be greater than a width of each of the fifth and sixth upper wirings 758 and 759 in the fifth direction D5.

In the semiconductor device, each of the first impurity regions 107 respectively formed on the peripheral active patterns 105 adjacent to each other in the fourth direction D4 may be electrically connected to the fourth upper wiring 757 through the first shared lower wiring (or the second shared lower wiring) and a corresponding one of the fourth upper contact plugs 727. Accordingly, compared to a case where the third lower wiring 607 and the fourth upper contact plug 727 are formed for each of the first impurity regions 107, the distance between the peripheral gate structures 330 in fourth direction D4 may be reduced. Accordingly, the degree of integration of the semiconductor device may be improved.

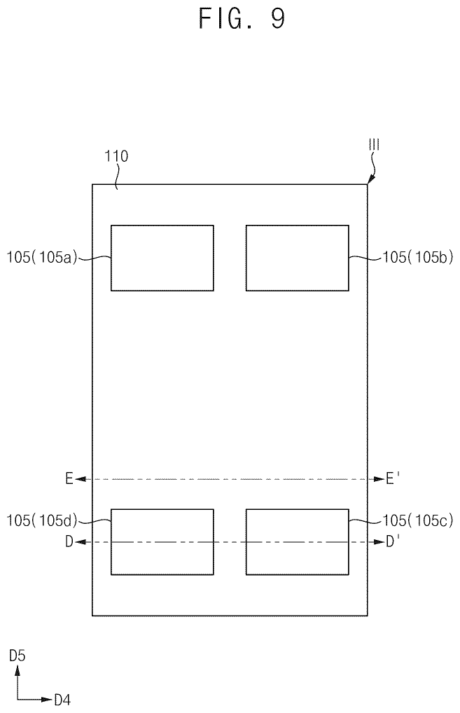

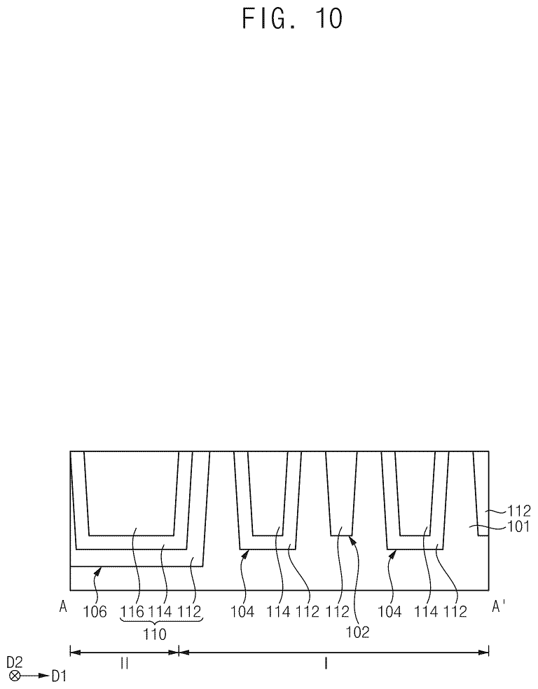

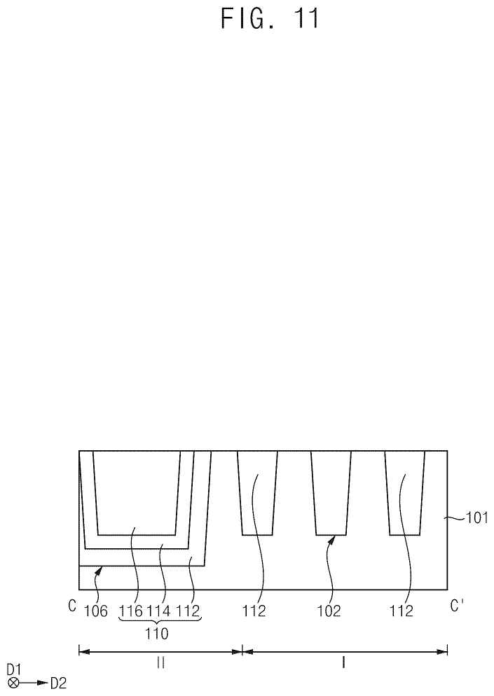

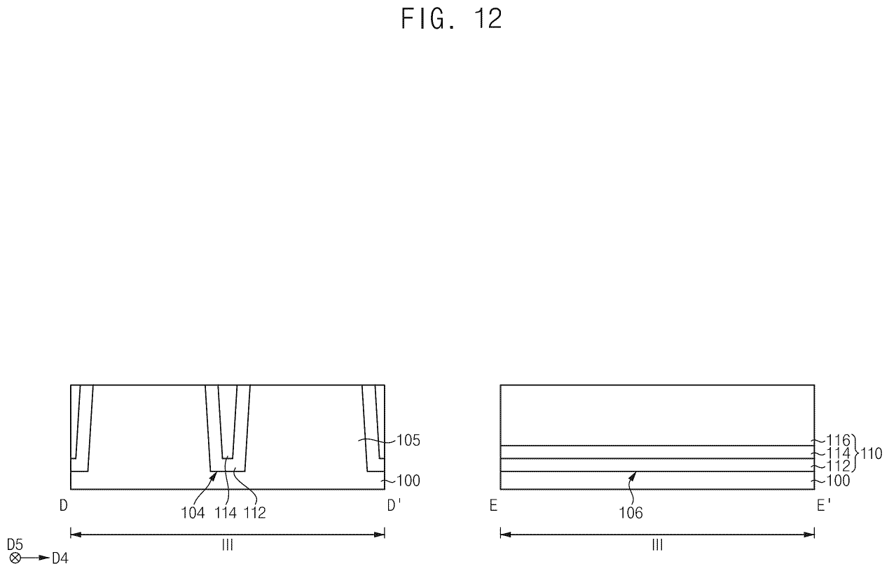

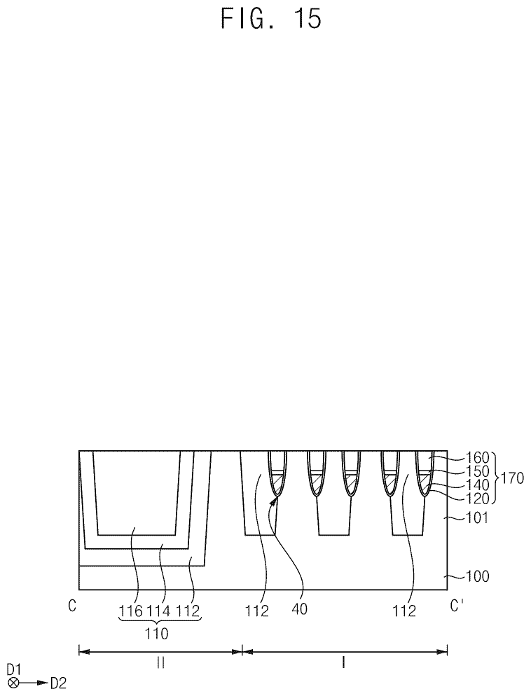

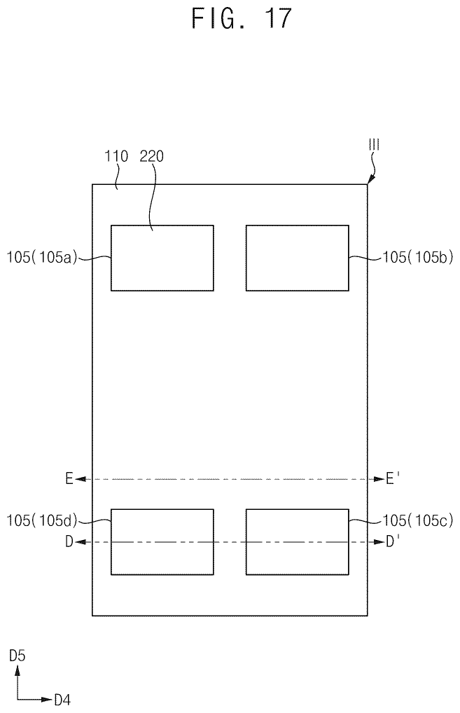

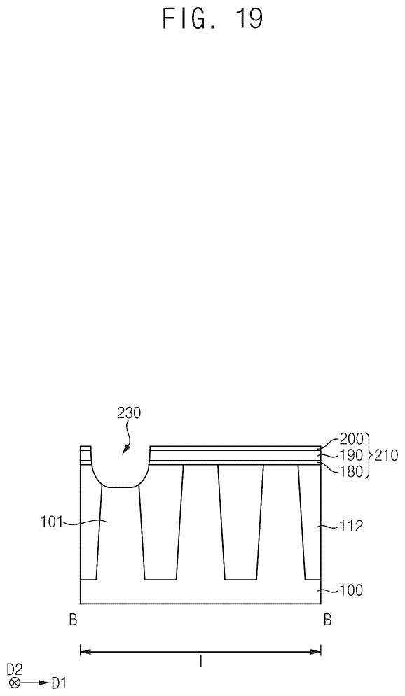

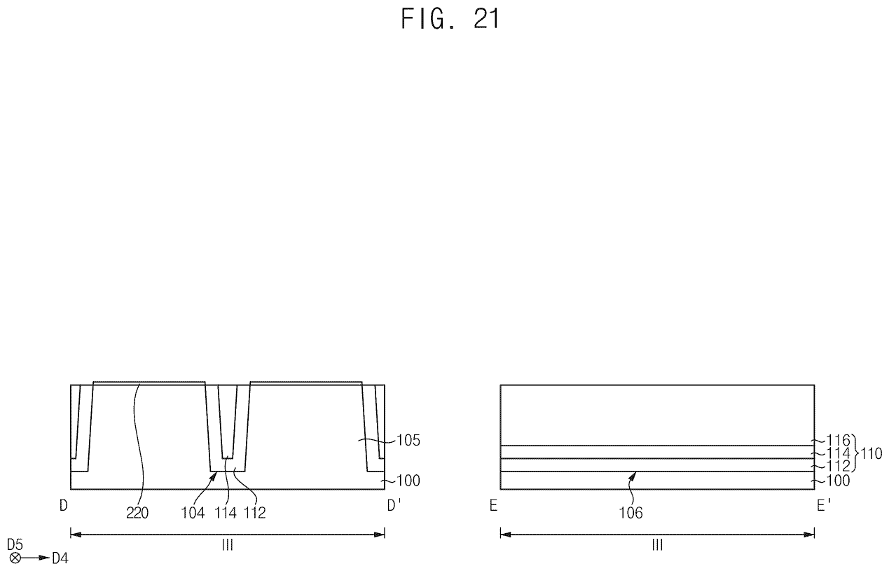

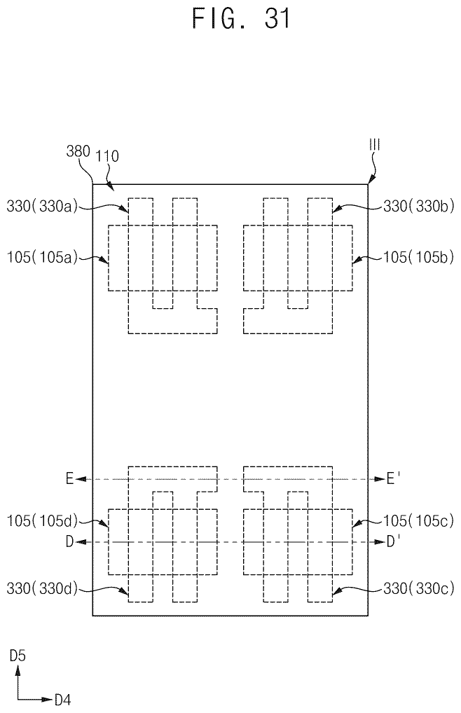

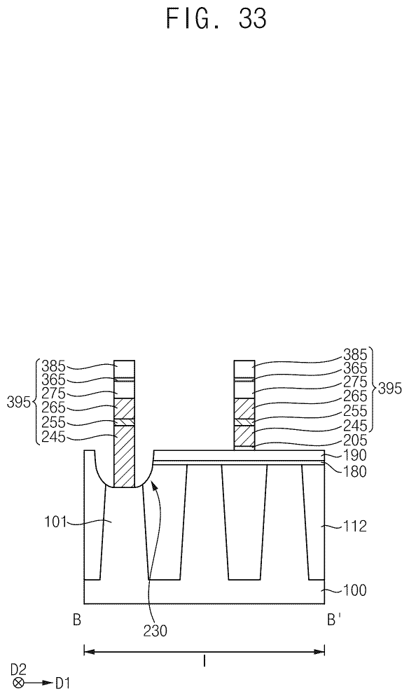

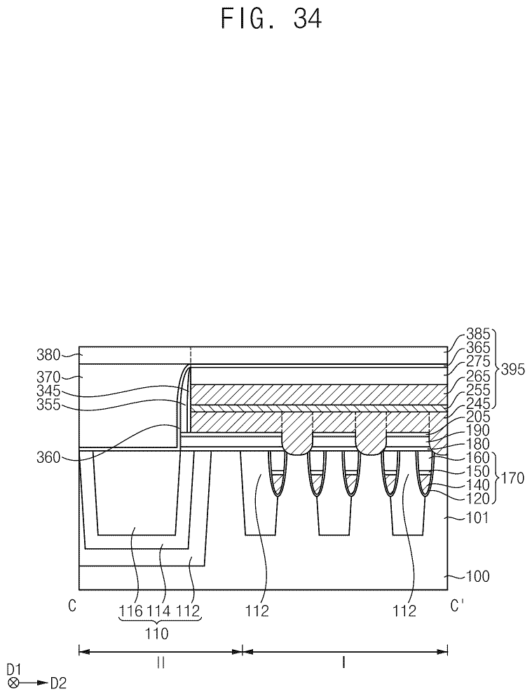

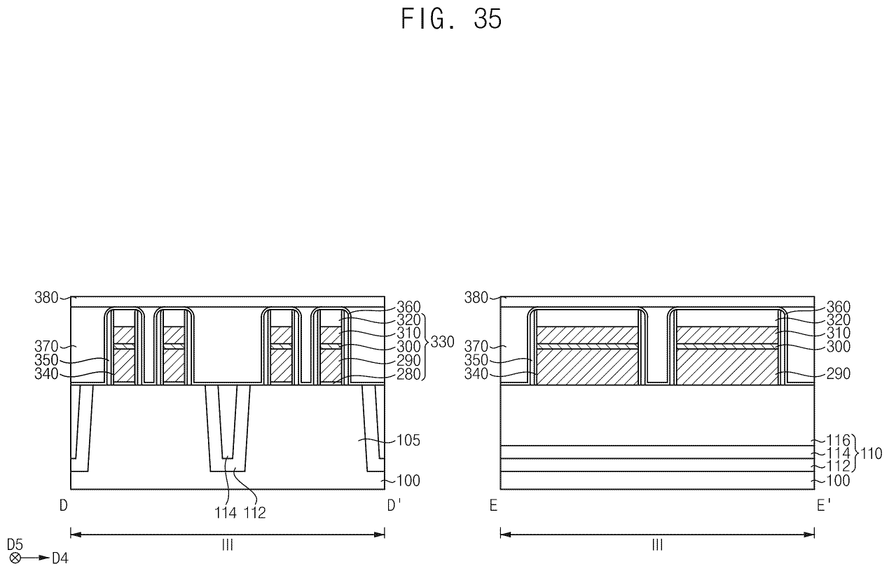

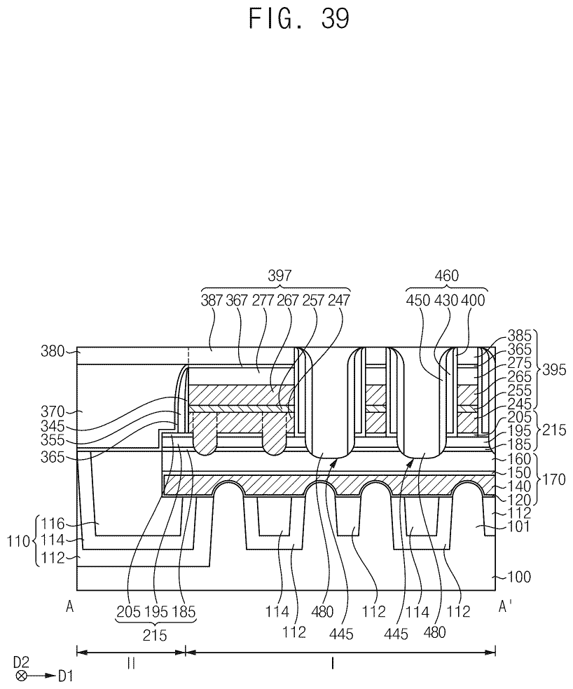

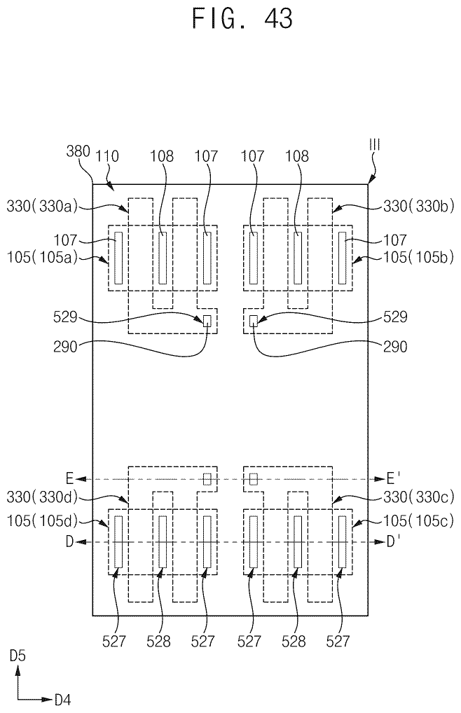

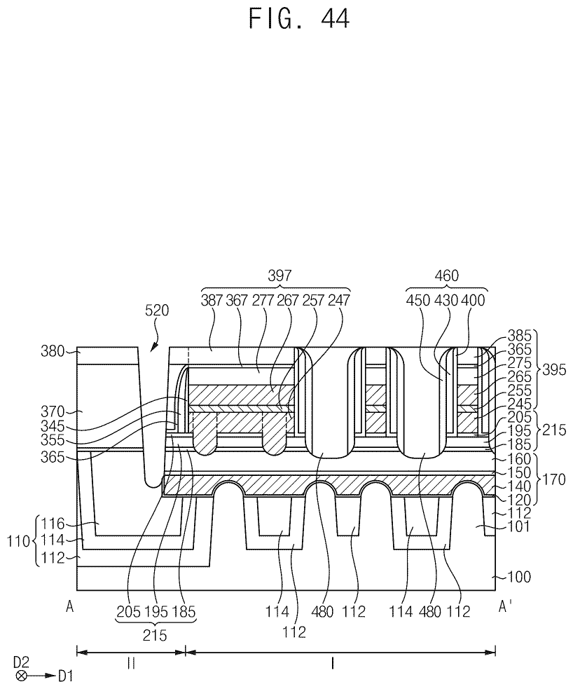

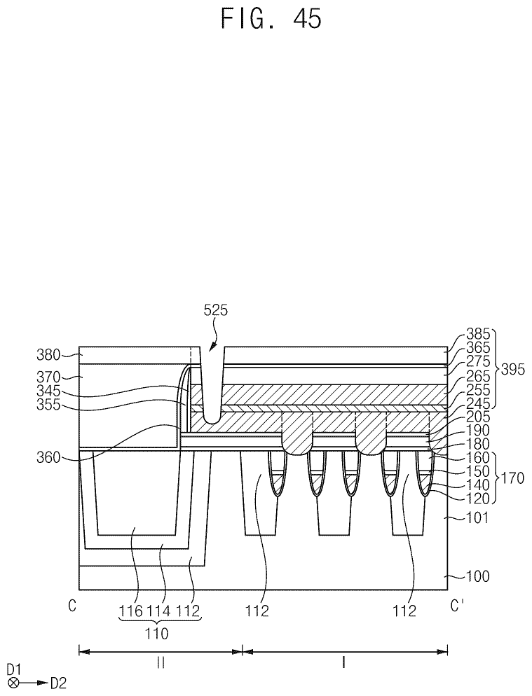

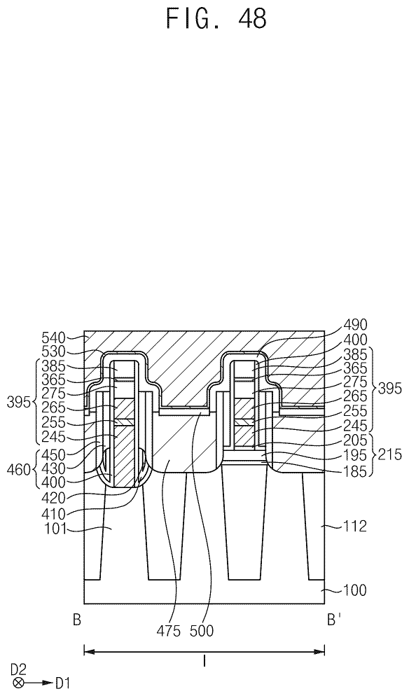

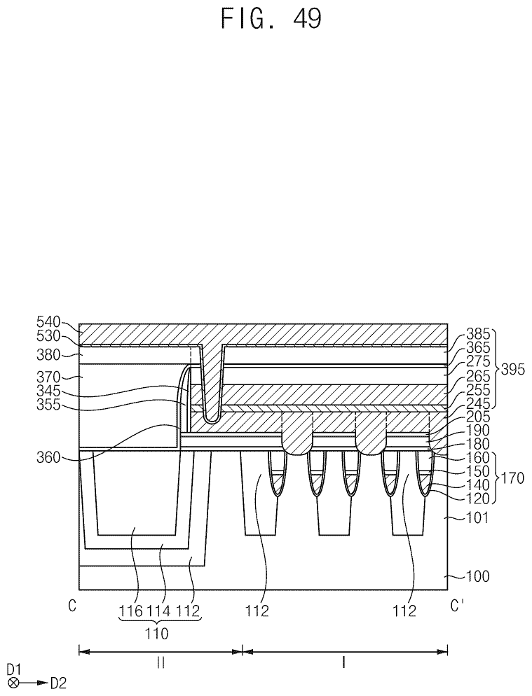

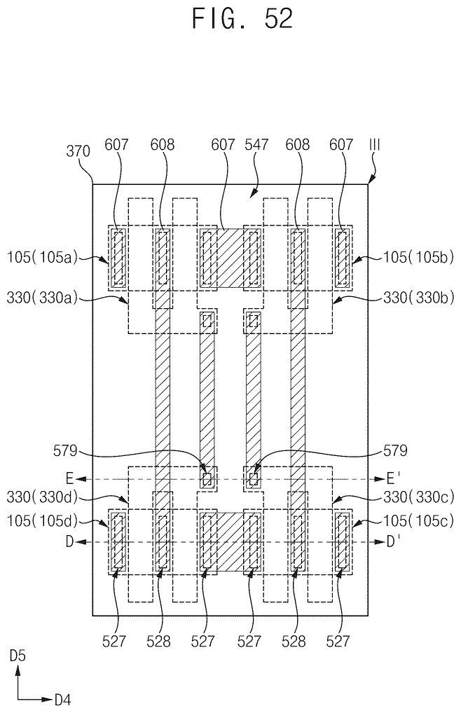

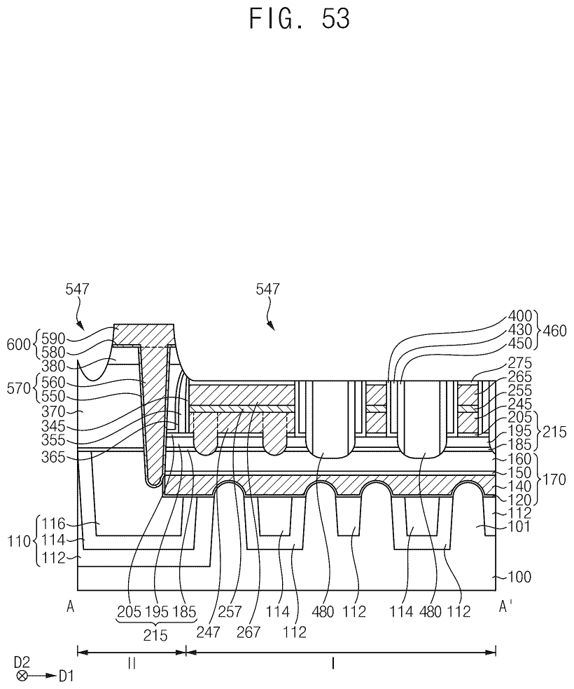

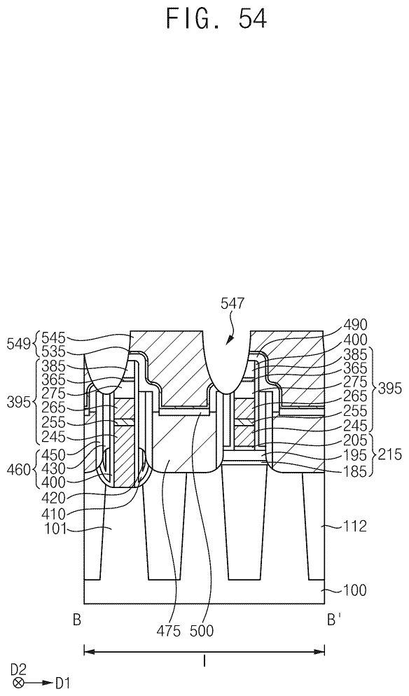

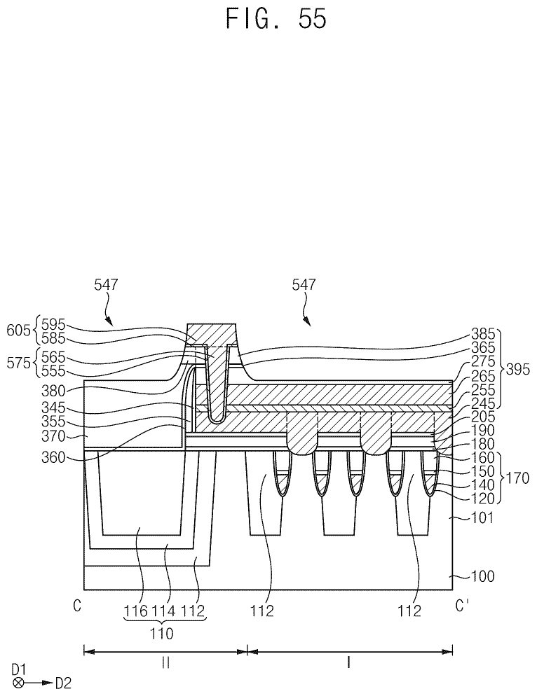

FIGS. 8 to 58 are plan views and cross-sectional views illustrating a method of manufacturing a semiconductor device according to example embodiments. Specifically, FIGS. 8, 13, 16, 24, 30, 38, 42, 51 and 57 are enlarged plan views of region X of FIG. 1, FIGS. 9, 17, 25, 31, 43 and 52 are enlarged plan views of region Y of FIG. 1, FIGS. 10, 14, 18, 22, 26, 32, 36, 39, 44, 47 and 53 are cross-sectional views taken along lines A-A′ of corresponding enlarged plan views of region X, respectively, FIGS. 19, 23, 27, 33, 37, 40-41, 48, 54 and 58 are cross-sectional views taken along lines B-B′ of corresponding enlarged plan views of region X, respectively, FIGS. 11, 15, 20, 28, 34, 45, 49 and 55 are cross-sectional views taken along lines C-C′ of corresponding enlarged plan views of region X, respectively, and FIGS. 12, 21, 29, 35, 46, 50 and 56 includes cross-sectional views taken along lines D-D′ and E-E′ of corresponding enlarged plan views of region Y, respectively.

Referring to FIGS. 8 to 12, a cell active pattern 101 and a peripheral active pattern 105 may be formed on the substrate 100 including first to third regions I, II and III.

The cell active pattern 101 and the peripheral active pattern 105 may be formed by removing an upper portion of the substrate 100 to form a recess structure. The cell active pattern 101 may extend in the third direction D3 on the first region I of the substrate 100 and the second region II of the substrate 100 adjacent thereto, and a plurality of cell active patterns 101 may be spaced apart from each other in each of the first and second directions D1 and D2. Additionally, a plurality of peripheral active patterns 105 may be spaced apart from each other in each of the first and second directions D1 and D2 on the third region III of the substrate 100. The peripheral active pattern 105 may include first to fourth peripheral active patterns 105a, 105b, 105c and 105d.

The recess structure may include first, second and third recesses 102, 104 and 106. The first recess 102 may be formed on the first region I of the substrate 100 between ones of the cell active patterns 101 spaced apart from each other by a relatively small distance, the second recess 104 may be formed between ones of the cell active patterns 101 spaced apart from each other by a relatively large distance on the first region I of the substrate 100 and between ones of the peripheral active patterns 105 spaced apart from each other by a relatively small distance on the third region III of the substrate 100, and the third recess 106 may be formed on the second region II of the substrate 100 or between ones of the peripheral active patterns 105 spaced apart from each other by a relatively large distance on the third region III of the substrate 100.

In example embodiments, the third recess 106 may have a width and/or a depth greater than a width and/or a depth of the second recess 104, and the second recess 104 may have a width and/or a depth greater than a width and/or a depth of the first recess 102.

An isolation structure 110 may be formed to cover or at least partially overlap sidewalls of the cell active pattern 101 and the peripheral active pattern 105.

Referring to FIGS. 13 to 15, an etching process may be performed on the cell active pattern 101 and the isolation structure 110 on the first region I of the substrate 100 and a portion of the second region II of the substrate 100 adjacent to the first region I of the substrate 100 to form a fourth recess 40.

In example embodiments, during the etching process, the cell active pattern 101 including a semiconductor material may be less etched than the isolation structure 110 including an insulating material due to the etching selectivity. Thus, the fourth recess 40 may have a concave upper surface on an upper surface of the cell active pattern 101.

A first gate insulation layer and a first conductive layer may be sequentially stacked on an inner wall of the fourth recess 40 and upper surfaces of the cell active pattern 101, the peripheral active pattern 105 and the isolation structure 110, the first gate insulation layer and the first conductive layer may be planarized until the upper surfaces of the cell active pattern 101, the peripheral active pattern 105 and the isolation structure 110 are exposed, and an upper portion of the first conductive layer may be removed by, e.g., an etch back process.

The planarization process may include a chemical mechanical polishing (CMP) process and/or an etch back process.

By the planarization process, a first gate insulation pattern 120 may be formed on the inner wall of the fourth recess 40, and by the etch back process, a first conductive pattern 140 may be formed on the first gate insulation pattern 120 to fill a lower portion of the fourth recess 40.

A second conductive pattern 150 may be formed on the first conductive pattern 140, a first gate mask layer may be formed on the second conductive pattern 150, the cell active pattern 101, the peripheral active pattern 105 and the isolation structure 110 to at least partially fill the fourth recess 40, and the first gate mask layer may be planarized until the upper surfaces of the cell active pattern 101, the peripheral active pattern 105 and the isolation structure 110 are exposed, so that a first gate mask 160 may be formed to at least partially fill an upper portion of the fourth recess 40. The first conductive pattern 140 and the second conductive pattern 150 may collectively form a gate electrode, and a first barrier pattern may be further formed between the first gate insulation pattern 120 and the first conductive pattern 140.

The first gate insulation pattern 120, the first barrier pattern, the first conductive pattern 140, the second conductive pattern 150 and the first gate mask 160 in the fourth recess 40 may collectively form a cell gate structure 170.

Referring to FIGS. 16 to 21, an insulation layer structure 210 may be formed on the first to third regions I, II and III of the substrate 100, a portion of the insulation layer structure 210 on the second and third regions II and III of the substrate 100 except for the portion of the second region II of the substrate 100 adjacent to the first region I of the substrate 100 may be removed.

For example, a thermal oxidation process may be performed on the peripheral active pattern 105 on the third region III of the substrate 100 to form a second gate insulation layer 220.

The insulation layer structure 210 may be patterned, and the cell active pattern 101, the isolation structure 110, and the first gate mask 160 of the cell gate structure 170 may be partially etched using the patterned insulation layer structure 210 as an etching mask to form a first opening 230. In example embodiments, the patterned insulation layer structure 210 may have a shape of a circle or an ellipse in a plan view, and a plurality of insulation layer structures 210 may be spaced apart from each other in the first and second directions D1 and D2 on the first region I of the substrate 100 and the portion of the second region II of the substrate 100 adjacent to the first region I of the substrate 100. Each of the insulation layer structures 210 may at least partially overlap opposite end portions in the third direction D3 of the cell active patterns 101 in a vertical direction substantially perpendicular to the upper surface of the substrate 100.

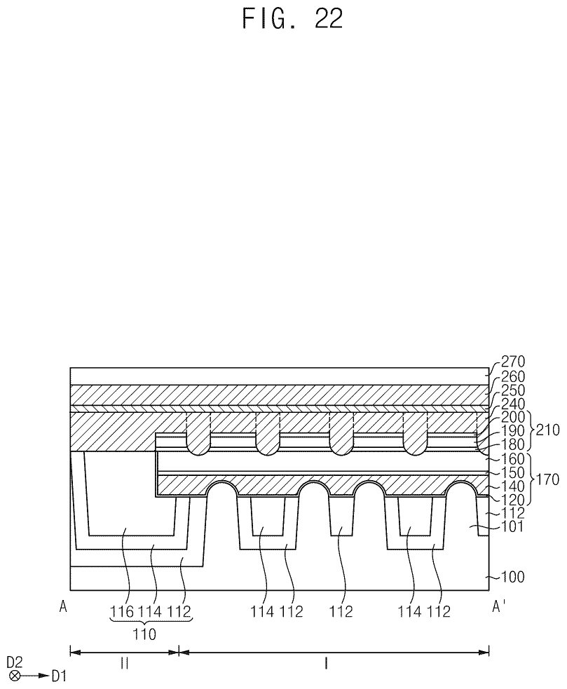

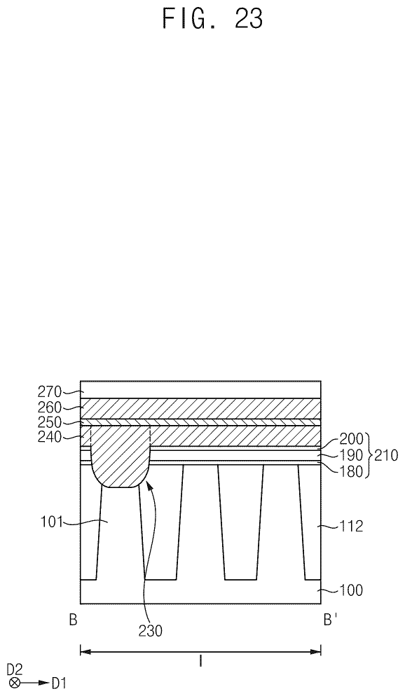

Referring to FIGS. 22 and 23, a third conductive layer 240, a second barrier layer 250, a fourth conductive layer 260 and a second mask layer 270 may be sequentially stacked on the insulation layer structure 210, the upper surfaces of the cell active pattern 101, the isolation structure 110 and the cell gate structure 170 exposed by the first opening 230 on the first region I of the substrate 100, the isolation structure 110 on the second region II of the substrate 100, and the second gate insulation layer 220 and the isolation structure 110 on the third region III of the substrate 100, which may collectively form a conductive structure layer. The third conductive layer 240 may at least partially fill the first opening 230.

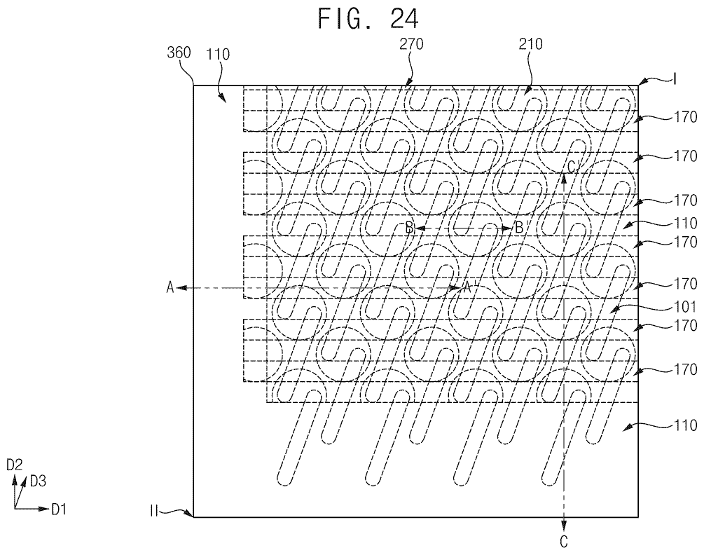

Referring to FIGS. 24 to 29, the conductive structure layer may be patterned to form a peripheral gate structure 330 on the third region III of the substrate 100.

The peripheral gate structure 330 may include a second gate insulation pattern 280, a third conductive pattern 290, a second barrier pattern 300, a fourth conductive pattern 310 and a second gate mask 320 sequentially stacked in the vertical direction substantially perpendicular to an upper surface of the substrate 100, and the third conductive pattern 290, the second barrier pattern 300 and the fourth conductive pattern 310 may collectively form a second gate electrode. The peripheral gate structures 330 may include first to fourth peripheral gate structures 330a, 330b, 330c and 330d.

In example embodiments, the peripheral gate structure 330 may include a first extension portion and a second extension portion. The first extension portion may extend in the fifth direction D5 and a plurality of first extension portions may be spaced apart from each other in the fourth direction D4. The first extension portion of the peripheral gate structure 330 may at least partially overlap the peripheral active pattern 105 in the vertical direction. The second extension portion may extend in the first direction D1 on the isolation structure 110 while contacting end portions in the fifth direction D5 of the first extension portions.

A portion of the conductive structure layer on an edge portion of the first region I of the substrate 100 adjacent to the second region II of the substrate 100 may also be removed, and thus the insulation layer structure 210, and the upper surfaces of the cell active pattern 101, the isolation structure 110 and the cell gate structure 170 exposed by the first opening 230 may also be partially exposed.

A first spacer structure may be formed on a sidewall of the peripheral gate structure 330, and a second spacer structure may be formed on a sidewall of the conductive structure layer remaining on the first region I of the substrate 100. The first spacer structure may include first and third spacers 340 and 350 stacked on the sidewall of the peripheral gate structure 330 in a horizontal direction substantially parallel to the upper surface of the substrate 100, and the second spacer structure may include second and fourth spacers 345 and 355 stacked on the sidewall of the conductive structure layer in the horizontal direction.

The first and second spacers 340 and 345 may be formed by forming a first spacer layer on the substrate 100 to cover or at least partially overlap the conductive structure layer and the peripheral gate structure 330 and anisotropically etching the first spacer layer. The third and fourth spacers 350 and 355 may be formed by forming a second spacer layer on the substrate 100 to cover or at least partially overlap the conductive structure layer, the peripheral gate structure 330 and the first and second spacers 340 and 345 and anisotropically etching the second spacer layer.

A first etch stop layer 360 may be formed on the substrate 100 to cover or at least partially overlap the conductive structure layer, the peripheral gate structure 330, the first and second spacer structures, and the isolation structure 110. The first etch stop layer 360 may include a nitride, e.g., silicon nitride.

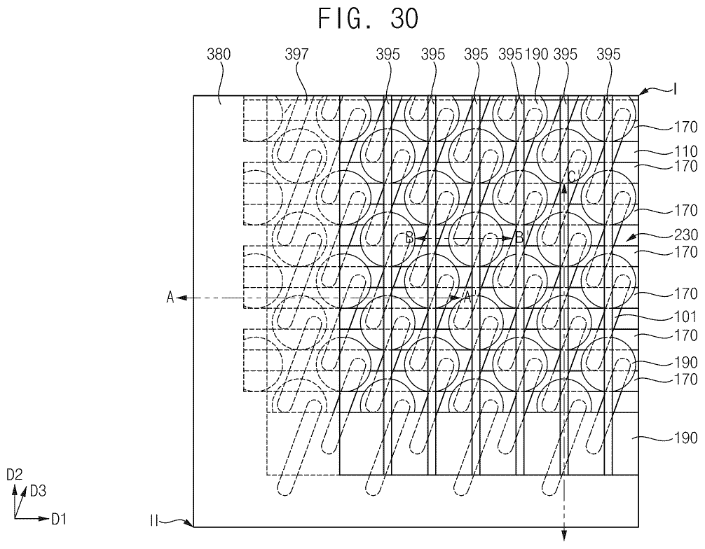

Referring to FIGS. 30 to 35, a first insulating interlayer 370 may be formed on the first etch stop layer 360 to a sufficient height, the first insulating interlayer 370 may be planarized until an upper surface of the peripheral gate structure 330 and an upper surface of a portion of the first etch stop layer 360 on the conductive structure layer are exposed, and a capping layer 380 may be formed on the first insulating interlayer 370 and the first etch stop layer 360.

A portion of the capping layer 380 on the first region I of the substrate 100 and the second region II of the substrate 100 adjacent thereto in the second direction D2 may be etched to form a first capping pattern 385, and the first etch stop layer 360, the second mask layer 270, the fourth conductive layer 260, the second barrier layer 250 and the third conductive layer 240 may be sequentially etched using the first capping pattern 385 as an etching mask.

In example embodiments, the first capping pattern 385 may extend in the second direction D2 on the first region I of the substrate 100 and the second region II of the substrate 100 adjacent thereto in the second direction D2, and a plurality of first capping patterns 385 may be formed to be spaced apart from each other in the first direction D1. The capping layer 380 may remain on the second and third regions II and III of the substrate 100.

By the etching process, on the first region I of the substrate 100 the second region II of the substrate 100 adjacent thereto in the second direction D2, a fifth conductive pattern 245, a third barrier pattern 255, a sixth conductive pattern 265, a second mask 275, a first etch stop pattern 365 and the first capping pattern 385 may be sequentially stacked on the first opening 230, and a third insulation pattern 205, the fifth conductive pattern 245, the third barrier pattern 255, the sixth conductive pattern 265, the second mask 275, the first etch stop pattern 365 and the first capping pattern 385 may be sequentially stacked on the second insulation layer 190 of the insulation layer structure 210 at an outside of the first opening 230.

Hereinafter, the fifth conductive pattern 245, the third barrier pattern 255, the sixth conductive pattern 265, the second mask 275, the first etch stop pattern 365 and the first capping pattern 385 sequentially stacked may be referred to as a bit line structure 395.

A dummy bit line structure 397 including a seventh conductive pattern 247, a fourth barrier pattern 257, an eighth conductive pattern 267, a second mask 277, a second etch stop pattern 367 and a second capping pattern 387 sequentially stacked and extending in the second direction D2 may be formed on a portion of the first region I of the substrate 100 adjacent to the second region II of the substrate 100 in the first direction D1, and the first etch stop layer 360 may remain on the peripheral gate structure 330, the first and second spacer structures, a portion of the insulation layer structure 210, the peripheral active pattern 105 and the isolation structure 110. Additionally, the capping layer 380 may remain on the first insulating interlayer 370.

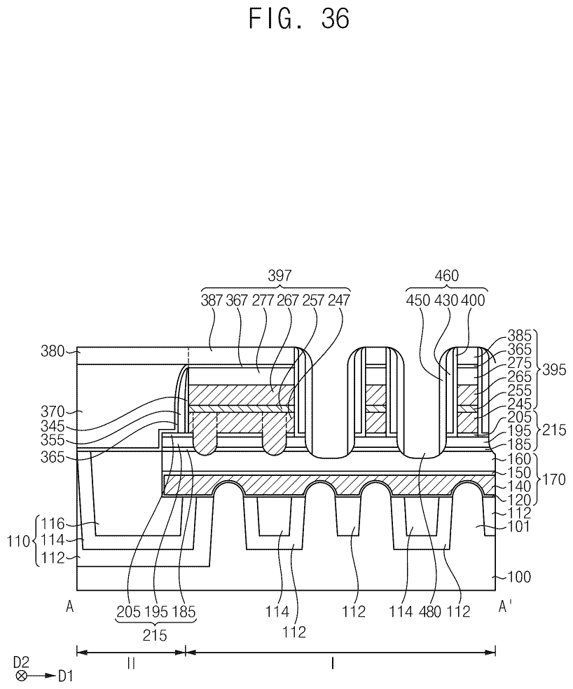

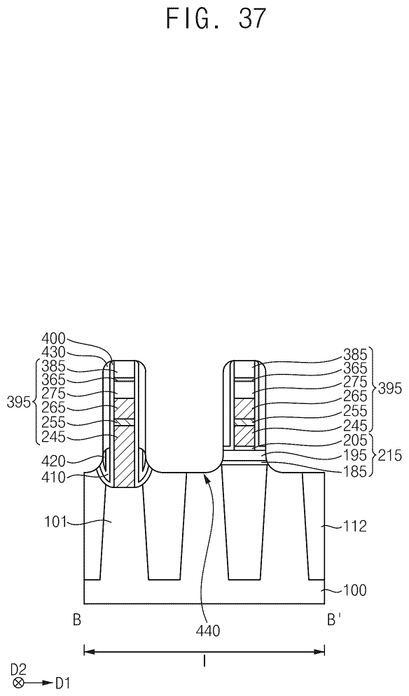

Referring to FIGS. 36 and 37, a fifth spacer layer may be formed on the substrate 100 to cover or at least partially overlap the bit line structure 395, the dummy bit line structure 397 and the capping layer 380, and fourth and fifth insulation layers may be sequentially formed on the fifth spacer layer.

The fifth spacer layer may also cover or at least partially overlap a sidewall of the third insulation pattern 205 between the second insulation layer 190 and the bit line structure 395, and the fifth insulation layer may fill the first opening 230.

The fifth spacer layer may include a nitride, e.g., silicon nitride, the fourth insulation layer may include an oxide, e.g., silicon oxide, and the fifth insulation layer may include a nitride, e.g., silicon nitride.

The fourth and fifth insulation layers may be etched by an etching process. In example embodiments, the etching process may be performed by a wet etch process using an etching solution including phosphorous acid (H₃PO₄), SC1, hydrogen fluoride (HF), and other portions of the fourth and fifth insulation layers except for a portion in the first opening 230 may be removed. Thus, most of an entire surface of the fifth spacer layer, that is, an entire surface except for a portion thereof in the first opening 230 may be exposed, and portions of the fourth and fifth insulation layers remaining in the first opening 230 may form fourth and fifth insulation patterns 410 and 420, respectively.

A sixth spacer layer may be formed on the exposed surface of the fifth spacer layer and the fourth and fifth insulation patterns 410 and 420 in the first opening 230, and may be anisotropically etched to form a sixth spacer 430 on the surface of the fifth spacer layer and the fourth and fifth insulation patterns 410 and 420 to cover or at least partially overlap a sidewall of the bit line structure 395. The sixth spacer layer may also be formed on a sidewall of the dummy bit line structure 397. The sixth spacer layer may include an oxide, e.g., silicon oxide.

A dry etching process may be performed to form a second opening 440 exposing the upper surface of the cell active pattern 101. An upper surface of the isolation structure 110 and an upper surface of the first gate mask 160 may also be exposed by the second opening 440.

By the dry etching process, portions of the fifth spacer layer on upper surfaces of the first and second capping patterns 385 and 387, the second insulation layer 190 and the capping layer 380 may be removed, and thus a fifth spacer 400 covering or at least partially overlapping the sidewall of the bit line structure 395 may be formed. The fifth spacer 400 may also cover or at least partially overlap the sidewall of the dummy bit line structure 397.

Additionally, during the dry etching process, the first and second insulation layers 180 and 190 may be partially removed, such that first and second insulation patterns 185 and 195 may remain under the bit line structure 395. The first to third insulation patterns 185, 195 and 205 that are sequentially stacked under the bit line structure 395 may collectively form an insulation pattern structure 215.

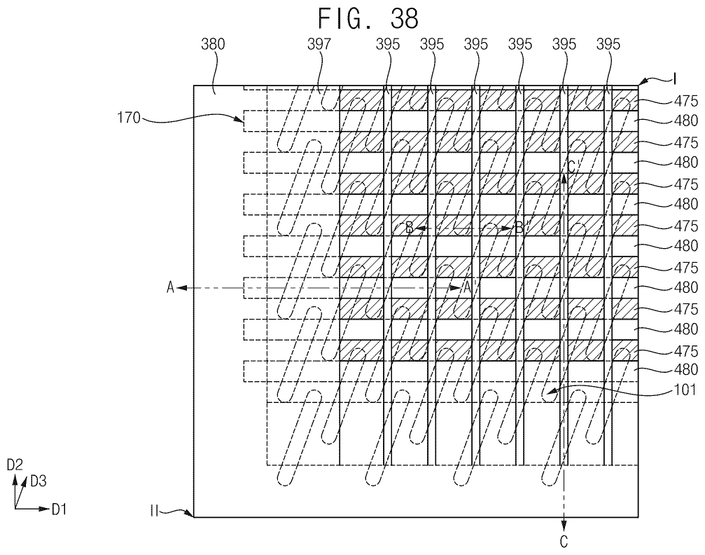

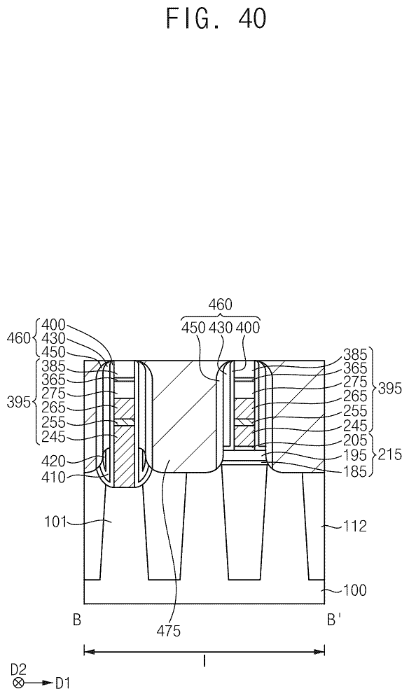

Referring to FIGS. 38 and 40, a seventh spacer layer may be formed on the upper surface of the first and second capping patterns 385 and 387, the upper surface of the capping layer 380, an outer sidewall of the sixth spacer 430, portions of upper surfaces of the fourth and fifth insulation patterns 410 and 420, and the upper surfaces of the cell active pattern 101, the isolation structure 110 and the first gate mask 160 exposed by the second opening 440, and may be anisotropically etched to form a seventh spacer 450 covering or at least partially overlapping an outer sidewall of sixth spacer 430 on the sidewalls of the bit line structure 395 and the dummy bit line structure 397. The seventh spacer layer may include a nitride, e.g., silicon nitride.

The fifth to seventh spacers 400, 430 and 450 sequentially stacked in the horizontal direction from the sidewall of the bit line structure 395 on the first region I of the substrate 100 may be referred to as a preliminary third spacer structure 460.

A first contact plug layer may be formed on the first region I of the substrate 100 to at least partially fill the second opening 440, the first contact plug layer may be planarized until the upper surfaces of the capping layer 380 and the first and second capping patterns 385 and 387 to form a first contact plug 475.

The first contact plug layer may extend in the second direction D2 between neighboring ones of the bit line structures 395 in the first direction D1 and between the bit line structure 395 and the dummy bit line structure 397 on the first region I of the substrate 100, and a plurality of first contact plug layers may be spaced apart from each other in the first direction D1. Each of the first contact plug layers may contact an upper surface of an end portion in the third direction D3 of the cell active pattern 101 extending in the third direction D3.

An etching mask having third openings, each of which may extend in the first direction D1, spaced apart from each other in the second direction D2 may be formed on the capping layer 380, the bit line structure 395, the dummy bit line structure and the first contact plug layer, and an etching process may be performed on the first contact plug layer using the etching mask to form a fourth opening 445.

In example embodiments, the third opening may at least partially overlap the cell gate structure 170 in the vertical direction, and the fourth opening 445 may expose an upper surface of the first gate mask 160 of the cell gate structure 170. As the fourth opening 445 is formed, the first contact plug layer extending in the second direction D2 may be divided into a plurality of first contact plugs 475 spaced apart from each other in the second direction D2.

After removing the etching mask, a fence pattern 480 may be formed to at least partially fill the fourth opening 445. A plurality of fence patterns 480 may be spaced apart from each other in the second direction D2 between the bit line structures 395 and between the bit line structure 395 and the dummy bit line structure 397. The fence pattern 480 may include a nitride, e.g., silicon nitride.

As illustrated above, the first contact plugs 475 and the fence patterns 480 that may be alternately and repeatedly arranged in the second direction D2 may be formed by forming the first contact plug layer extending in the second direction D2 between the bit line structures 395, forming the fourth openings 445 spaced apart from each other in the second direction D2 and extending through the first contact plug layer, and at least partially filling the fourth opening 445 by the fence pattern 480, however, the inventive concept may not be limited thereto.

In some embodiments, the first contact plugs 475 and the fence patterns 480 that may be alternately and repeatedly arranged in the second direction D2 may be formed by forming a fence layer extending in the second direction D2 between the bit line structures 395, forming fifth openings through the fence layer spaced apart from each other in the second direction D2 to divide the fence layer into the fence patterns 480, forming the first contact plug layer on the fence layer to at least partially fill the fifth openings, and planarizing the first contact plug layer to form the first contact plugs 475.

In some embodiments, the first contact plugs 475 and the fence patterns 480 that may be alternately and repeatedly arranged in the second direction D2 may be formed by forming a sacrificial layer including an oxide, e.g., silicon oxide and extending in the second direction D2 between the bit line structures 395, forming the fence patterns 480 through the sacrificial layer spaced apart from each other in the second direction D2, removing the sacrificial layer to form sixth openings, forming the first contact plug layer to at least partially fill the sixth openings, and planarizing the first contact plug layer to form the first contact plugs 475.

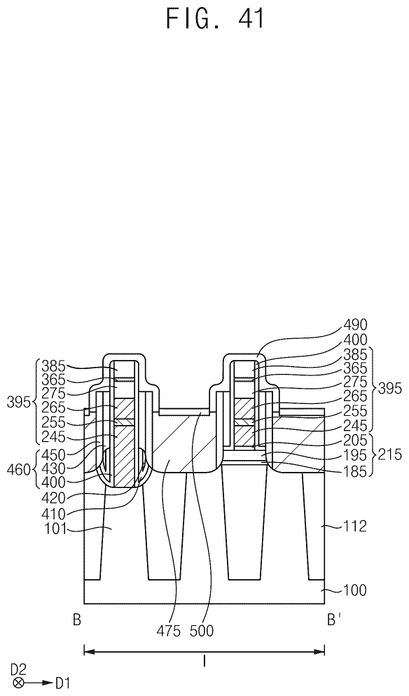

Referring to FIG. 41, an upper portion of the first contact plug 475 may be removed to expose an upper portion of the preliminary third spacer structure 460 on the sidewalls of the bit line structure 395 and the dummy bit line structure 397, and upper portions of the sixth and seventh spacers 430 and 450 of the exposed preliminary third spacer structure 460 may be removed.

An etch back process may be further performed to remove an upper portion of the first contact plug 475. Thus, an upper surface of the first contact plug 475 may be lower than uppermost surfaces of the sixth and seventh spacers 430 and 450.

An eighth spacer layer may be formed on the bit line structure 395, the dummy bit line structure 397, the preliminary third spacer structure 460, the fence pattern 480, the capping layer 380, and the first contact plug 475, and may be anisotropically etched so that an eighth spacer 490 may be formed to cover or at least partially overlap the preliminary third spacer structure 460 on each of opposite sidewalls of the bit line structure 395 in the first direction D1 and that an upper surface of the first contact plug 475 may not be covered or overlapped to be exposed.

An ohmic contact pattern 500 may be formed on the exposed upper surface of the first contact plug 475. In example embodiments, the ohmic contact patterns 500 may be formed by forming a first metal layer on the first and second capping patterns 385 and 387, the capping layer 380, the fence pattern 480, the eighth spacer 490, and the first contact plug 475, thermally treating the first metal layer, and removing an unreacted portion of the first metal layer. The ohmic contact patterns 500 may include a metal silicide, e.g., cobalt silicide, nickel silicide, titanium silicide, etc.

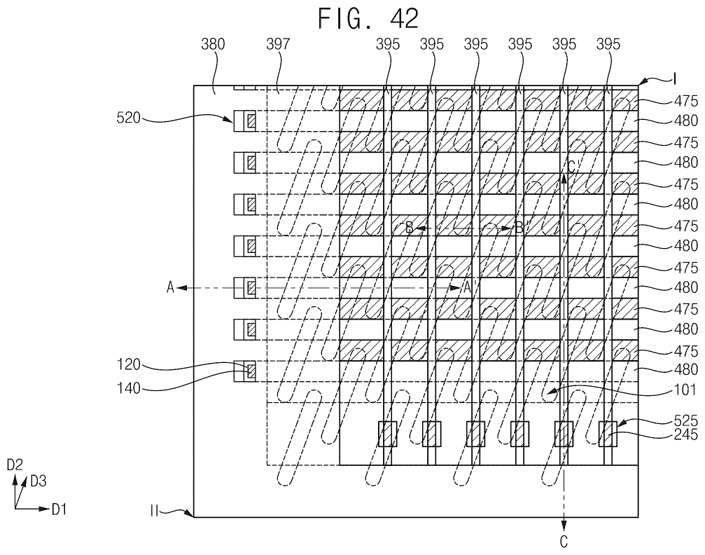

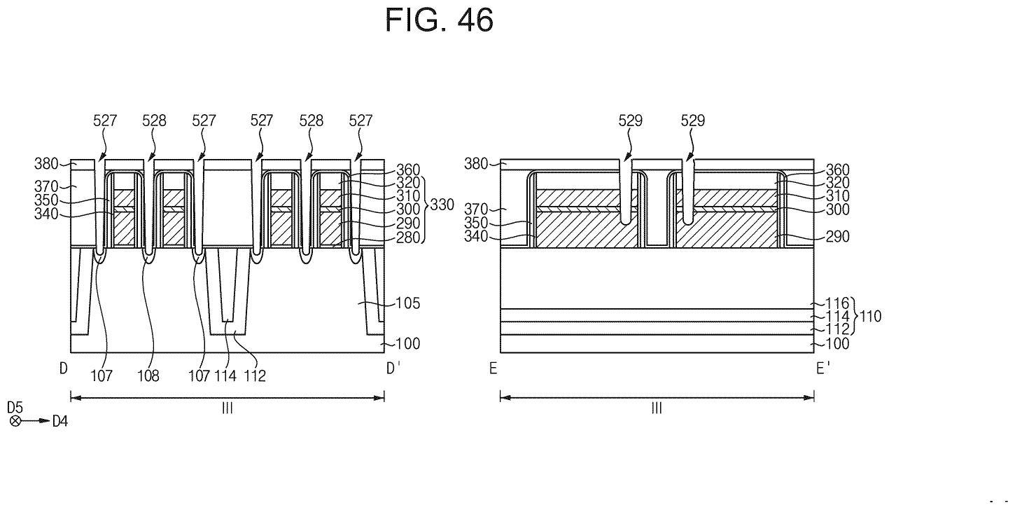

Referring to FIGS. 42 and 46, a seventh opening 520 may be formed through a portion of the capping layer 380 on the portion of the second region II of the substrate 100 adjacent to the first region I of the substrate 100 in the first direction D1, and the first insulating interlayer 370, the first etch stop layer 360, the insulation pattern structure 215, the isolation structure 110, the first gate mask 160 and the second conductive pattern 150 to expose the first conductive pattern 140, and the seventh opening 520 may also expose the first gate insulation pattern 120 on the sidewall of the first conductive pattern 140.

Also, an eighth opening 525 may be formed through a portion of the first capping pattern 385 on the portion of the second region II of the substrate 100 adjacent to the first region I of the substrate 100 in the first direction D1, and the first etch stop layer 360, the second mask 275, the sixth conductive pattern 265 and third barrier pattern 255 to expose the fifth conductive pattern 245.

Also, a ninth opening 527 may be formed through a portion of the capping layer 380 on the portion of the third region III of the substrate 100, and the first insulating interlayer 370 to expose a portion of the upper surface of the peripheral active pattern 105 adjacent to the peripheral gate structure 330.

Also, a tenth opening 528 may be formed through a portion of the capping layer 380 on the portion of the third region III of the substrate 100, and the first insulating interlayer 370 to expose a portion of the upper surface of the peripheral active pattern 105 adjacent to the peripheral gate structure 330.

In example embodiments, the tenth opening 528 may expose the portion of the upper surface of the peripheral active pattern 105 between second sides of the first extensions of the peripheral gate structure 330 facing each other in the fourth direction D4, and the ninth opening 527 may expose the portion of the upper surface of the peripheral active pattern 105 adjacent to a first side of the first extension of the peripheral gate structure 330 that is opposite from the second side of the first extension of the peripheral gate structure 330 in the fourth direction D4.

Also, an eleventh opening 529 may be formed through a portion of the capping layer 380 on the portion of the third region III of the substrate 100, and the first etch stop layer 360, the second gate mask 320, the fourth conductive pattern 310 and the second barrier pattern 300 to expose the third conductive pattern 290 of the peripheral gate structure 330.

First and second impurity regions 107 and 108 may be formed on upper portions of the peripheral active pattern 105 exposed by the ninth and tenth openings 527 and 528, respectively. In example embodiments, the first and second impurity regions 107 and 108 may be formed, e.g., an ion implantation process.

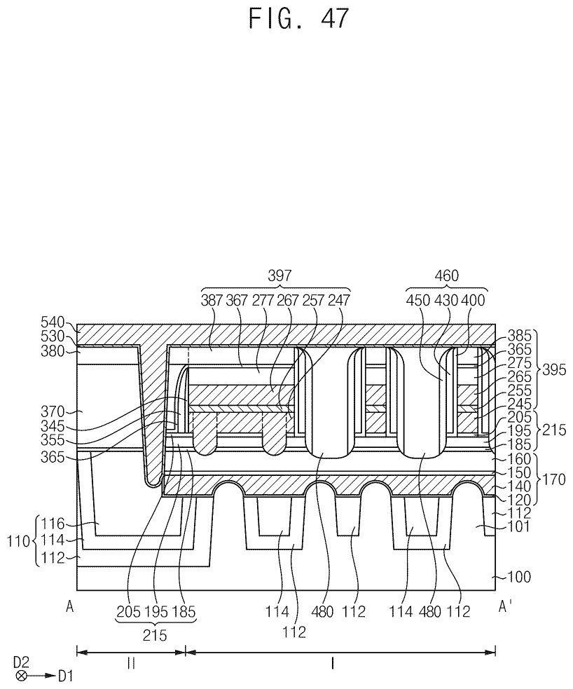

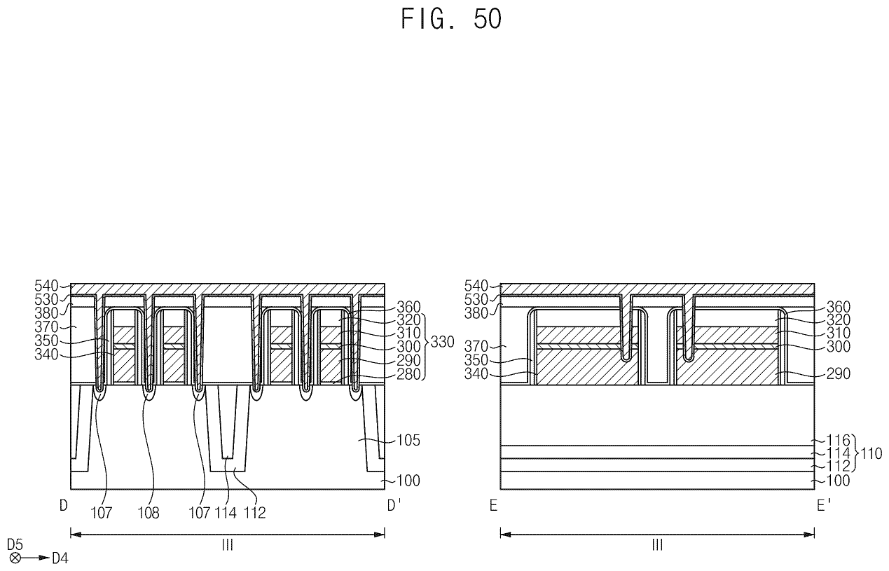

Referring to FIGS. 47 and 50, a fifth barrier layer 530 may be formed on the first and second capping patterns 385 and 387, the fence pattern 480, the eighth spacer 490, the ohmic contact pattern 500 and the first contact plug 475 on the first region I of the substrate 100, and the capping layer 380, a sidewall of the seventh opening 520 and the first conductive pattern 140, the first gate insulation pattern 120 and the isolation structure 110 exposed by the seventh opening 520, a sidewall of the eighth opening 525 and the fifth conductive pattern 245 exposed by the eighth opening 525 on the second region II of the substrate 100, and the capping layer 380, a sidewall of the ninth opening 527 and the first impurity region 107 exposed by the ninth opening 527, a sidewall of the tenth opening 528 and the second impurity region 108 exposed by the tenth opening 528, a sidewall of the eleventh opening 529 and the third conductive pattern 290 exposed by the eleventh opening on the third region III of the substrate 100. A second metal layer 540 may be formed on the fifth barrier layer 530 to at least partially fill a space between the bit line structures 395, a space between the bit line structure 395 and the dummy bit line structure 397, and the seventh to eleventh openings 520, 525, 527, 528 and 529.

Referring to FIGS. 51 to 56, the second metal layer 540 and the fifth barrier layer 530 may be patterned.

Thus, a second contact plug 549 may be formed on the first region I of the substrate 100. Additionally, a first lower wiring 600 may be formed on a portion of the second region II of the substrate 100 adjacent to the first region I of the substrate 100 in the first direction D1, and a second lower wiring 605 may be formed on a portion of the second region II of the substrate 100 adjacent to the first region I of the substrate 100 in the second direction D2. Also, third to fifth lower wirings 607, 608 and 609 may be formed on the third region III of the substrate 100.

A twelfth opening 547 may be formed between the second contact plug 549 and the first to fifth lower wirings 600, 605, 607, 608 and 609.

The twelfth opening 547 may be formed by removing not only the second metal layer 540 and the fifth barrier layer 530 but also the first and second capping patterns 385 and 387, the fence pattern 480, the capping layer 380, the preliminary third spacer structure 460, the eighth spacer 490, the first etch stop layer 360, the first etch stop pattern 365, and the first mask 275. Accordingly, an upper surface of the sixth spacer 430 may be exposed.

As the twelfth opening 547 is formed, the second metal layer 540 and the fifth barrier layer 530 may be respectively transformed into a first metal pattern 545 and a fifth barrier pattern 535 covering or at least partially overlapping a lower surface of the first metal pattern 545, which may collectively form a second contact plug 549 on the first region I of the substrate 100. In example embodiments, the second contact plug 549 may at least partially overlap the first contact plug 475 in the vertical direction. In example embodiments, a plurality of second contact plugs 549 may be formed to be spaced apart from each other in each of the first and second directions D1 and D2, and may be arranged in a honeycomb pattern or a lattice pattern in a plan view. Each of the second contact plugs 549 may have a shape of a circle, an ellipse, or a polygon in a plan view.

The first contact plug 475, the ohmic contact pattern 500 and the second contact plug 549 sequentially stacked on the first region I of the substrate 100 may collectively form a first contact plug structure.

The first lower wiring 600 may include a third metal pattern 590 and a seventh barrier pattern 580 covering or at least partially overlapping a lower surface of the third metal pattern 590, and a first lower contact plug 570 including a second metal pattern 560 and a sixth barrier pattern 550 may be formed in the seventh opening 520.

The second lower wiring 605 may include a fifth metal pattern 595 and a ninth barrier pattern 585 covering or at least partially overlapping a lower surface of the fourth metal pattern 595, and a second lower contact plug 575 including a fourth metal pattern 565 and an eighth barrier pattern 555 may be formed in the eighth opening 525.

In example embodiments, the first lower wiring 600 may at least partially overlap the seventh opening 520 in the vertical direction, and a plurality of first lower wirings 600 may be spaced apart from each other in the second direction D2. The first lower wiring 600 may be electrically connected to the first conductive pattern 140 through the first lower contact plug 570, and thus may apply electrical signals to the cell gate structure 170.

In example embodiments, the second lower wiring 605 may overlap the eighth opening 525 in the vertical direction, and a plurality of second lower wirings 605 may be spaced apart from each other in the first direction D1. The second lower wiring 605 may be electrically connected to the fifth conductive pattern 245 through the second lower contact plug 575, and thus may apply electrical signals to the bit line structure 395.

The third lower wiring 607 may include a seventh metal pattern 597 and an eleventh barrier pattern 587 covering or at least partially overlapping a lower surface thereof. A third lower contact plug 577 including a sixth metal pattern 567 and a tenth barrier pattern 557 may be formed in the ninth opening 527.

The fourth lower wiring 608 may include a ninth metal pattern 598 and a thirteenth barrier pattern 588 covering or at least partially overlapping a lower surface thereof. A fourth lower contact plug 578 including an eighth metal pattern 568 and a twelfth barrier pattern 558 may be formed in the tenth opening 528.

The fifth lower wiring 609 may include an eleventh metal pattern 599 and a fifteenth barrier pattern 589 covering or at least partially overlapping a lower surface thereof. A fifth lower contact plug 579 including a tenth metal pattern 569 and a fourteenth barrier pattern 559 may be formed in the eleventh opening 529.

In example embodiments, the third lower wiring 607 may at least partially overlap the third lower contact plug 577 in the vertical direction, and a plurality of third lower wirings 607 may be spaced apart from each other in the fourth and fifth directions D4 and D5. The third lower wiring 607 may be electrically connected to the first impurity region 107 through the third lower contact plug 577.

In example embodiments, the fourth lower wiring 608 may at least partially overlap the fourth lower contact plug 578 in the vertical direction. The fourth lower wiring 608 may extend in the fifth direction D5, and a plurality of fourth lower wirings 608 may be spaced apart from each other in the fourth direction D4. The fourth lower wiring 608 may be electrically connected to the second impurity region 108 through the fourth lower contact plug 578.

In example embodiments, the fifth lower wiring 609 may at least partially overlap the fifth lower contact plug 579 in the vertical direction. The fifth lower wiring 609 may extend in the fifth direction D5, and a plurality of fifth lower wirings 609 may be spaced apart from each other in the fourth direction D4. The fifth lower wiring 609 may be electrically connected to the third conductive pattern 290 of the peripheral gate structure 330 through the fifth lower contact plug 579.

Some of the third lower wirings 607 may commonly contact upper surfaces of the third lower contact plugs 577 respectively formed on the peripheral active patterns 105 adjacent to each other in the fourth direction D4.

Hereinafter, for convenience of explanation, the third lower wiring 607 that commonly contacts the upper surfaces of the third lower contact plugs 577 respectively formed on the first and second peripheral active patterns 105a and 105b adjacent to each other in the fourth direction D4 may be referred to as the first shared lower wiring, and the third lower wiring 607 that commonly contacts the upper surfaces of the third lower contact plugs 577 respectively formed on the third and fourth peripheral active patterns 105c and 105d adjacent to each other in the fourth direction D4 may be referred to as the second shared lower wiring.

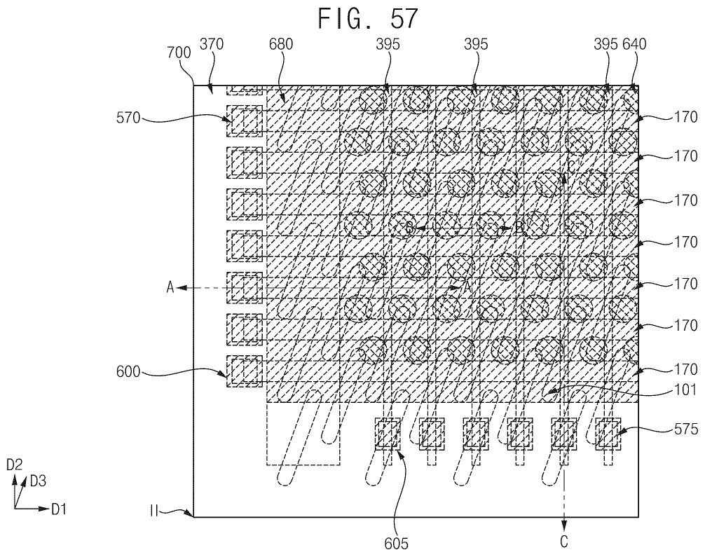

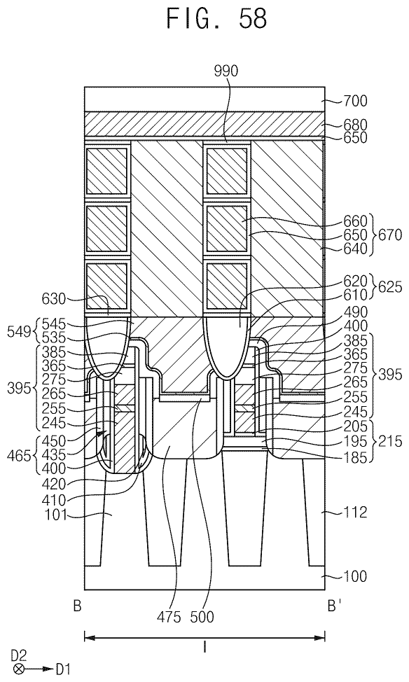

Referring to FIGS. 57 and 58, the sixth spacer 430 may be removed to form an air gap 435 connected to the twelfth opening 547. The sixth spacer 430 may be removed by, e.g., a wet etching process.

In example embodiments, not only a first portion of the sixth spacer 430 on the sidewalls of the bit line structure 395 and the dummy bit line structure 397, which is directly exposed by the twelfth opening 547, but also a second portion of the sixth spacer 430, which is parallel to the first portion in the horizontal direction, may be removed. That is, not only a portion of the sixth spacer 430 exposed by the twelfth opening 547 not to be covered or overlapped by the second contact plug 549 but also a portion of the sixth spacer 430 covered or at least partially overlapped by the second contact plug 549 may be removed.

A second insulating interlayer 625 may be formed to at least partially fill the twelfth opening 547.

In example embodiments, the second insulating interlayer 625 may include sixth and seventh insulation patterns 610 and 620 sequentially stacked. The sixth insulation pattern 610 may include a material having a poor gap filling characteristic, and thus the air gap 435 may not be filled with or include the sixth insulation pattern 610, but may remain, which may be referred to as an air spacer 435. The fifth and seventh spacers 400 and 450 and the air spacer 435 may collectively form a third spacer structure 465. The air spacer 435 may be a spacer including air. The seventh insulation pattern 620 may include an oxide, e.g., silicon oxide or a nitride, e.g., a silicon nitride.

A capacitor 670 and a plate electrode 680 may be formed on the second insulating interlayer 625 and the second contact plug 549. The capacitor 670 and the plate electrode 680 may be formed by following processes.

A second etch stop layer 630 may be formed on the second insulating interlayer 625 and the second contact plug 549, and a mold layer and a support layer 990 may be alternately and repeatedly stacked on the second etch stop layer 630. The second etch stop layer 630 may include an insulating nitride, e.g., silicon boronitride, the mold layer may include an oxide, e.g., silicon oxide, and the support layer 990 may include an insulating nitride, e.g., silicon nitride.

A thirteenth opening may be formed through the support layer 990, the mold layer and the second etch stop layer 630 to expose an upper surface of the second contact plug 549, a first capacitor electrode layer may be formed on the upper surface of the second contact plug 549 exposed by the thirteenth opening, a sidewall of the thirteenth opening and an upper surface of an uppermost support layer 990, and the first capacitor electrode layer may be planarized until an upper surface of the uppermost support layer 990 is exposed to form a first capacitor electrode 640 within the thirteenth opening. The planarization process may include, e.g., a chemical mechanical polishing (CMP) process and/or an etch back process.

The support layer 990 and the mold layer may be partially removed to form a fourteenth opening exposing the upper surface of the second etch stop layer 630, and the mold layer may be removed through the fourteenth opening.

In example embodiments, the mold layer may be removed by a wet etching process, and accordingly, a fifteenth opening may be formed to expose a sidewall of the first capacitor electrode 640 and the upper surface of the second etch stop layer 630. The support layers 990 may remain on the sidewall of each of the first capacitor electrodes 640, and accordingly, surface of each of the support layers 990 may be exposed by the fifteenth opening.

A dielectric layer 650 may be formed on the sidewall of each of the first capacitor electrodes 640, the upper surface of the second etch stop layer 630 and the surface of each of the support layers 990 exposed by the fifteenth opening, and a second capacitor electrode layer may be formed on the dielectric layer 650 to at least partially fill a remaining portion of the fifteenth opening. The dielectric layer 650 and the second capacitor electrode layer may also be stacked on an upper surface of the first capacitor electrode 640 and the upper surface of the uppermost support layer 990.

A wet etching process may be performed on the second capacitor electrode layer to form a second capacitor electrode 660 within the sixth opening. The first capacitor electrode 640, the dielectric layer 650 and the second capacitor electrode 660 may collectively form the capacitor 670.

The plate electrode 680 may be formed on an upper surface and a sidewall of the capacitor 670 and an upper surface of the second insulating interlayer 625.

Thereafter, a third insulating interlayer 700 covering or at least partially overlapping a sidewall and an upper surface of the plate electrode 680 may be formed on the plate electrode 680, the first to fifth lower wirings 600, 605, 607, 608 and 609 and the second insulating interlayer 625.

Referring to FIGS. 1 to 7 again, a fourth insulating interlayer 710 may be formed on the third insulating interlayer 700.

A first upper contact plug 722 extending through the third and fourth insulating interlayers 700 and 710 in the first region I of the substrate 100 and contacting the upper surface of the plate electrode 680, second and third upper contact plugs 724 and 726 extending through the third and fourth insulating interlayers 700 and 710 on the second region II of the substrate 100 and respectively contacting upper surfaces of the first and second lower wirings 600 and 605, and fourth to sixth upper contact plugs 727, 728 and 729 extending through the third and fourth insulating interlayers 700 and 710 in the third region III of the substrate 100 and respectively contacting upper surfaces of the third to fifth lower wirings 607, 608 and 609 may be formed.

A fifth insulating interlayer 740 may be formed on the first to sixth upper contact plugs 722, 724, 726, 727, 728 and 729.

A first upper wiring 750 extending through the fifth insulating interlayer 740 and contacting an upper surface of at least one of the first to third upper contact plugs 722, 724 and 726, and fourth to sixth upper wirings 757, 758 and 759 extending through the fifth insulating interlayer 740 and respectively contacting upper surfaces of fourth to sixth upper contact plugs 727, 728 and 729 may be formed. Accordingly, manufacturing of the semiconductor device may be completed.

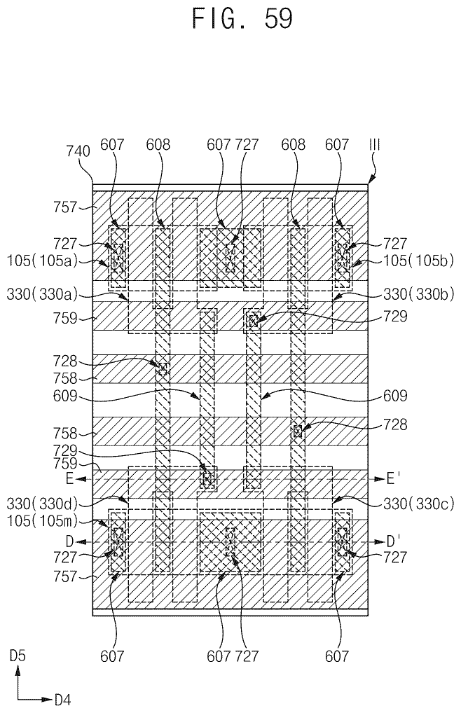

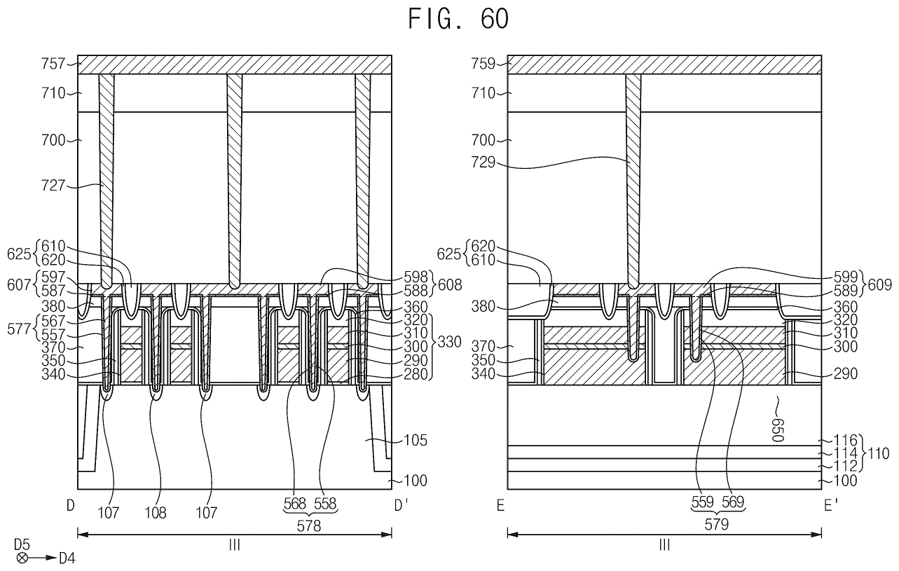

FIGS. 59 and 60 are a plan view and a cross-sectional view illustrating a semiconductor device according to example embodiments, corresponding to FIGS. 3 and 7. The semiconductor device may be substantially the same as or similar to a semiconductor device of FIGS. 1 to 7, except for relationship between the peripheral active pattern 105 and the peripheral gate structure 330, and thus repeated explanations are omitted herein.

Referring to FIGS. 59 and 60, unlike the semiconductor device of FIGS. 1 to 7 in which the first to fourth peripheral gate structures 330a, 330b, 330c and 330d are respectively formed on first to fourth peripheral active patterns 105a, 105b, 105c and 105d, the peripheral active patterns 105 neighboring in the fourth direction D4 and separated in the fourth direction D4 by the isolation structure 110, for example, the third and fourth peripheral active patterns 105c and 105d, may be merged with each other (e.g., integrally formed). Hereinafter, for convenience of explanation, the peripheral active patterns 105 merged with each other may be referred to as a fifth peripheral active pattern 105m. The third and fourth peripheral gate structures 330c and 330d may be formed on a single fifth peripheral active pattern 105m.

While the present inventive concepts have been shown and described with reference to example embodiments thereof, it will be understood by those of ordinary skill in the art that various changes in form and details may be made thereto without departing from the spirit and scope of the present inventive concepts as set forth by the following claims.

What is claimed is:

1. A semiconductor device comprising:
a first active pattern and a second active pattern on a substrate, the first active pattern and the second active pattern spaced apart from each other in a first direction substantially parallel to an upper surface of the substrate;
a first gate structure extending in a second direction on the first active pattern, the second direction substantially parallel to the upper surface of the substrate and intersecting the first direction;
a second gate structure extending in the second direction on the second active pattern and spaced apart from the first gate structure in the first direction;
a first impurity region in an upper portion of the first active pattern and adjacent to a first side of the first gate structure facing the second gate structure in the first direction;
a second impurity region in an upper portion of the second active pattern and adjacent to a second side of the second gate structure facing the first gate structure in the first direction;
a first lower contact plug and a second lower contact plug contacting an upper surface of the first impurity region and an upper surface of the second impurity region, respectively;
a shared lower wiring contacting upper surfaces of the first lower contact plug and the second lower contact plug; and
a first upper contact plug contacting an upper surface of the shared lower wiring.

2. The semiconductor device of claim 1, further comprising an upper wiring on and electrically connected to the first upper contact plug.

3. The semiconductor device of claim 1, further comprising:
a third impurity region in the upper portion of the first active pattern and adjacent to a third side of the first gate structure that is opposite to the first side of the first gate structure in the first direction; and
a fourth impurity region in the upper portion of the second active pattern and adjacent to a fourth side of the second gate structure that is opposite to the second side of the second gate structure in the first direction.

4. The semiconductor device of claim 3, further comprising a third lower contact plug and a fourth lower contact plug contacting an upper surface of the third impurity region and an upper surface of the fourth impurity region, respectively.

5. The semiconductor device of claim 4, further comprising a first lower wiring and a second lower wiring contacting an upper surface of the third lower contact plug and an upper surface of the fourth lower contact plug, respectively.

6. The semiconductor device of claim 5, further comprising a second upper contact plug and a third upper contact plug contacting an upper surface of the first lower wiring and an upper surface of the second lower wiring, respectively.

7. The semiconductor device of claim 6, further comprising a fifth lower contact plug and a sixth lower contact plug contacting an upper surface of the first gate structure and an upper surface of the second gate structure, respectively.

8. The semiconductor device of claim 7, further comprising a third lower wiring and a fourth lower wiring contacting an upper surface of the fifth lower contact plug and an upper surface of the sixth lower contact plug, respectively.

9. The semiconductor device of claim 8, further comprising a fourth upper contact plug and a fifth upper contact plug contacting an upper surface of the third lower wiring and an upper surface of the fourth lower wiring.

10. The semiconductor device of claim 9, further comprising an upper wiring on and electrically connected to the first upper contact plug, wherein the upper wiring is a source power (VSS) line or a drain power (VDD) line, the first lower wiring and the second lower wiring are output lines, and the third lower wiring and the fourth lower wiring are input lines.

11. A semiconductor device comprising:
a first active pattern and a second active pattern on a substrate, the first active pattern and the second active pattern spaced apart from each other in a first direction substantially parallel to an upper surface of the substrate;
a first gate structure and a second gate structure extending in a second direction on the first active pattern and spaced apart from each other in the first direction, the second direction substantially parallel to the upper surface of the substrate and intersecting the first direction;
a third gate structure extending in the second direction on the second active pattern;
a first source region in an upper portion of the first active pattern and adjacent to a first side of the first gate structure;
a first drain region in the upper portion of the first active pattern and adjacent to each of a second side of the first gate structure and a third side of the second gate structure facing each other in the first direction;
a second source region in the upper portion of the first active pattern and adjacent to a fourth side of the second gate structure that is opposite to the third side of the second gate structure in the first direction;
a third source region in an upper portion of the second active pattern and adjacent to a fifth side of the third gate structure facing the fourth side of the second gate structure in the first direction;
a second drain region in the upper portion of the second active pattern adjacent to a sixth side of the third gate structure facing the fifth side of the third gate structure in the first direction;
a first contact plug, a second lower contact plug and a third lower contact plug on the first source region, the second source region, and the third source region, respectively;
a first lower wiring contacting an upper surface of the first contact plug; and
a second lower wiring contacting an upper surface of the second lower contact plug and an upper surface of the third lower contact plug,
wherein a width in the first direction of the second lower wiring is greater than a width in the first direction of the first lower wiring.

12. The semiconductor device of claim 11, further comprising a first upper contact plug and a second upper contact plug on the first lower wiring and the second lower wiring, respectively.

13. The semiconductor device of claim 12, further comprising an upper wiring on and contacting the first upper contact plug and the second upper contact plug, wherein the upper wiring is a source power (VSS) line or a drain power (VDD) line.

14. The semiconductor device of claim 13, further comprising:
a fourth lower contact plug and a fifth lower contact plug contacting an upper surface of the first drain region and an upper surface of the second drain region, respectively; and
a third lower wiring and a fourth lower wiring contacting an upper surface of the fourth lower contact plug and an upper surface of the fifth lower contact plug, respectively, and
wherein the third lower wiring and the fourth lower wiring are output lines.

15. A semiconductor device comprising:
a cell active pattern on a substrate comprising a cell region and a peripheral circuit region;
a cell gate structure extending in a first direction substantially parallel to an upper surface of the substrate and in an upper portion of the cell active pattern;
a bit line structure contacting a central portion of an upper surface of the cell active pattern and extending in a second direction substantially parallel to the upper surface of the substrate and substantially perpendicular to the first direction;
a contact plug structure contacting a first end and a second end of the upper surface of the cell active pattern;
a capacitor on the contact plug structure;
a peripheral active pattern on the peripheral circuit region;
a first peripheral gate structure and a second peripheral gate structure extending in a third direction on the peripheral active pattern and spaced apart from each other in a fourth direction, the third direction and the fourth direction substantially parallel to the upper surface of the substrate and intersecting each other;
a first impurity region in an upper portion of the peripheral active pattern and adjacent to a first side of the first peripheral gate structure facing the second peripheral gate structure in the fourth direction;
a second impurity region in the upper portion of the peripheral active pattern and adjacent to a second side of the second peripheral gate structure facing the first peripheral gate structure in the fourth direction;
a first lower contact plug and a second lower contact plug contacting an upper surface of the first impurity region and an upper surface of the second impurity region, respectively;
a shared lower wiring contacting upper surfaces of the first lower contact plug and the second lower contact plug; and
an upper contact plug contacting an upper surface of the shared lower wiring.

16. The semiconductor device of claim 15, wherein the peripheral active pattern comprises a first peripheral active pattern and a second peripheral active pattern, the first peripheral gate structure and the second peripheral gate structure are on the first peripheral active pattern and the second peripheral active pattern, respectively, and the first impurity region and the second impurity region are on the first peripheral active pattern and the second peripheral active pattern, respectively.

17. The semiconductor device of claim 15, wherein the contact plug structure comprises a third lower contact plug, an ohmic contact pattern and a fourth lower contact plug on each of the first end and the second end of the upper surface of the cell active pattern.

18. The semiconductor device of claim 17, wherein the shared lower wiring at least partially overlaps the fourth lower contact plug in a fifth direction substantially parallel to the upper surface of the substrate.

19. The semiconductor device of claim 15, wherein the upper contact plug at least partially overlaps the capacitor in a fifth direction substantially parallel to the upper surface of the substrate.

20. The semiconductor device of claim 15, further comprising an upper wiring on the upper contact plug, wherein the upper wiring is a source power (VSS) line or a drain power (VDD) line.
